(19) United States
(12) Patent Application Publication
(10) Pub. No.: US 2007/0085632 A1
(43) Pub. Date: Apr. 19, 2007

(54) Acoustic galvanic isolator

(76) Inventors: John D. Larson III, Palo Alto, CA (US); Ian Hardcastle, Sunnyvale, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/253,464

(22) Filed: Oct. 18, 2005

(51) Int. Cl. H03H 9/54

(52) U.S. Cl. 333/187

(57) ABSTRACT

Embodiments of the acoustic galvanic isolator comprise a carrier signal source, a modulator connected to receive an information signal and the carrier signal, a demodulator, and an electrically-isolating acoustic coupler connected between the modulator and the demodulator. In an exemplary embodiment, the electrically-isolating acoustic coupler comprises film bulk acoustic resonators (FBARs). An electrically-isolating acoustic coupler is physically small and is inexpensive to fabricate yet is capable of passing information signals having data rates in excess of 100 Mbit/s and has a substantial breakdown voltage between its inputs and its outputs.

### RELATED APPLICATIONS

This disclosure is related to the following simultaneously-filed disclosures: Acoustic Galvanic Isolator Incorporating Single Decoupled Stacked Bulk Acoustic Resonator of John D. Larson III (Agilent Docket No. 10051180-1); Acoustic Galvanic Isolator Incorporating Single Insulated Decoupled Stacked Bulk Acoustic Resonator With Acoustically-Resonant Electrical Insulator of John D. Larson III (Agilent Docket No. 10051205-1); Acoustic Galvanic Isolator Incorporating Film Acoustically-Coupled Transformer of John D. Larson III et al. (Agilent Docket No. 10051206-1); and Acoustic Galvanic Isolator Incorporating Series-Connected Decoupled Stacked Bulk Acoustic Resonators of John D. Larson III et al. (Agilent Docket No. 10051207-1), all of which are assigned to the assignee of this disclosure and are incorporated by reference.

### BACKGROUND

A galvanic isolator allows an information signal to pass from its input to its output but has no electrical conduction path between its input and its output. The lack of an electrical conduction path allows the galvanic isolator to prevent unwanted voltages from passing between its input and its output. Strictly speaking, a galvanic isolator blocks only DC voltage, but a typical galvanic isolator additionally blocks a.c. voltage, such as voltages at power line and audio frequencies. An example of a galvanic isolator is a data coupler that passes a high data rate digital information signal but blocks DC voltages and additionally blocks low-frequency a.c. voltages.

One example of a data coupler is an opto-isolator such as the opto-isolators sold by Agilent Technologies, Inc. In an opto-isolator, an electrical information signal is converted to a light signal by a light-emitting diode (LED). The light signal passes through an electrically non-conducting light-transmitting medium, typically an air gap or an optical waveguide, and is received by a photodetector. The photodetector converts the light signal back to an electrical signal. Galvanic isolation is provided because the light signal can pass through the electrically non-conducting light-transmitting medium without the need of metallic conductors.

Other data couplers include a transformer composed of a first coil magnetically coupled to a second coil. Passing the electrical information signal through the first coil converts the electrical information signal to magnetic flux. The magnetic flux passes through air or an electrically non-conducting permeable magnetic material to the second coil. The second coil converts the magnetic flux back to an electrical signal. The transformer allows the high data rate information signal to pass but blocks transmission of DC voltages and low-frequency a.c. voltages. The resistance of the conveyor of the magnetic flux is sufficient to prevent DC voltages and low-frequency a.c. voltages from passing from input to output. Blocking capacitors are sometimes used to provide similar isolation.

Inexpensive opto-isolators are typically limited to data rates of about 10 Mb/s by device capacitance, and from power limitations of the optical devices. The transformer approach requires that the coils have a large inductance yet be capable of transmitting the high data rate information signal. Such conflicting requirements are often difficult to reconcile. Using capacitors does not provide an absolute break in the conduction path because the information signal is transmitted electrically throughout. More successful solutions convert the electrical information signal to another form of signal, e.g., light or a magnetic flux, and then convert the other form of signal back to an electrical signal. This allows the electrical path between input and output to be eliminated.

Many data transmission systems operate at speeds of 100 Mb/s. What is needed is a compact, inexpensive galvanic isolator capable of operating at speeds of 100 Mb/s and above.

### SUMMARY OF THE INVENTION

In a first aspect, the invention provides an acoustic galvanic isolator. Embodiments of the acoustic galvanic isolator comprise a carrier signal source, a modulator connected to receive an information signal and the carrier signal, a demodulator, and an electrically-isolating acoustic coupler connected between the modulator and the demodulator. In an exemplary embodiment, the electrically-isolating acoustic coupler comprises film bulk acoustic resonators (FBARs).

In a second aspect, the invention provides method for galvanically isolating an information signal. Embodiments of the method comprise providing an electrically-isolating acoustic coupler and a carrier signal, modulating the carrier signal with the information signal to form a modulated electrical signal, acoustically coupling the modulated electrical signal through the electrically-isolating acoustic coupler; and recovering the information signal from the modulated electrical signal acoustically coupled through the electrically-isolating acoustic coupler.

An electrically-isolating acoustic coupler is physically small and is inexpensive to fabricate yet is capable of acoustically coupling information signals having data rates in excess of 100 Mbit/s and has a substantial breakdown voltage between its inputs and its outputs.

### BRIEF DESCRIPTION OF THE DRAWINGS

FIG. 1 is a block diagram showing an acoustic galvanic isolator in accordance with an embodiment of the invention.

FIG. 2 is a schematic diagram showing an example of an acoustic coupler in accordance with a first embodiment of the invention that may be used as the electrically-isolating acoustic coupler of the acoustic galvanic isolator shown in FIG. 1.

FIG. 3 is a graph showing the frequency response characteristic of an exemplary embodiment of the decoupled stacked bulk acoustic resonator (DSBAR) that forms part of the acoustic coupler shown in FIG. 2.

FIG. 4A is a plan view showing a practical example of the acoustic coupler shown in FIG. 2.

FIGS. 4B and 4C are cross-sectional views along the section lines 4B-4B and 4C-4C, respectively, shown in FIG. 4A.

FIG. 5A is an enlarged view of the portion marked 5A in FIG. 4B showing a first embodiment of the acoustic decoupler.

FIG. 5B is an enlarged view of the portion marked 5A in FIG. 4B showing a second embodiment of the acoustic decoupler of the example of the acoustic decoupler.

FIG. 6 is a schematic diagram showing an example of an acoustic coupler in accordance with a second embodiment of the invention that may be used as the electrically-isolating acoustic coupler of the acoustic galvanic isolator shown in FIG. 1.

FIG. 7A is a plan view showing a practical example of the acoustic coupler shown in FIG. 6.

FIGS. 7B and 7C are cross-sectional views along the section lines 7B-7B and 7C-7C, respectively, shown in FIG. 7A.

FIG. 8 is a schematic diagram showing an example of an acoustic coupler in accordance with a third embodiment of the invention that may be used as the electrically-isolating acoustic coupler of the acoustic galvanic isolator shown in FIG. 1.

FIG. 9A is a plan view showing a practical example of the acoustic coupler shown in FIG. 8.

FIGS. 9B and 9C are cross-sectional views along the section lines 9B-9B and 9C-9C, respectively, shown in FIG. 9A.

FIG. 10 is a schematic diagram showing an example of an acoustic coupler in accordance with a fourth embodiment of the invention that may be used as the electrically-isolating acoustic coupler of the acoustic galvanic isolator shown in FIG. 1.

FIG. 11A is a plan view showing a practical example of the acoustic coupler shown in FIG. 10.

FIGS. 11B and 11C are cross-sectional views along the section lines 11B-11B and 11C-11C, respectively, shown in FIG. 11A.

FIG. 12 is a schematic diagram showing an example of an acoustic coupler in accordance with a fifth embodiment of the invention that may be used as the electrically-isolating acoustic coupler of the acoustic galvanic isolator shown in FIG. 1.

FIG. 13A is a plan view showing a practical example of the acoustic coupler shown in FIG. 12.

FIGS. 13B and 13C are cross-sectional views along the section lines 13B-13B and 13C-13C, respectively, shown in FIG. 13A.

FIG. 14A is a schematic diagram showing an example of an acoustic coupler in accordance with a sixth embodiment of the invention that may be used as the electrically-isolating acoustic coupler of the acoustic galvanic isolator shown in FIG. 1;

FIG. 14B is a schematic diagram showing an example of an acoustic coupler in accordance with the sixth embodiment of the invention in which the constituent FACTs are fabricated on a common substrate.

FIG. 15 is a plan view showing a practical example of the acoustic coupler shown in FIG. 14B.

FIG. 16 is a schematic diagram showing an example of an acoustic coupler in accordance with a seventh embodiment of the invention that may be used as the electrically-isolating acoustic coupler of the acoustic galvanic isolator shown in FIG. 1.

FIG. 17 is a graph showing the frequency response characteristics of an example of the acoustic coupler shown in FIG. 16 (solid line) and of one of its constituent DSBARs (broken line).

FIG. 18A is a plan view showing a practical example of the acoustic coupler shown in FIG. 16.

FIGS. 18B and 18C are cross-sectional views along the section lines 18B-18B and 18C-18C, respectively, shown in FIG. 18A.

FIG. 19 is a schematic diagram showing an example of an acoustic coupler in accordance with an eighth embodiment of the invention that may be used as the electrically-isolating acoustic coupler of the acoustic galvanic isolator shown in FIG. 1.

FIG. 20A is a plan view showing a practical example of the acoustic coupler shown in FIG. 19.

FIGS. 20 and 20C are cross-sectional views along the section lines 20B-20B and 20C-20C, respectively, shown in FIG. 20A.

FIG. 21 is a flow chart showing an example of a method in accordance with an embodiment of the invention for galvanically isolating an information signal.

### DETAILED DESCRIPTION

1. Acoustic Galvanic Isolator

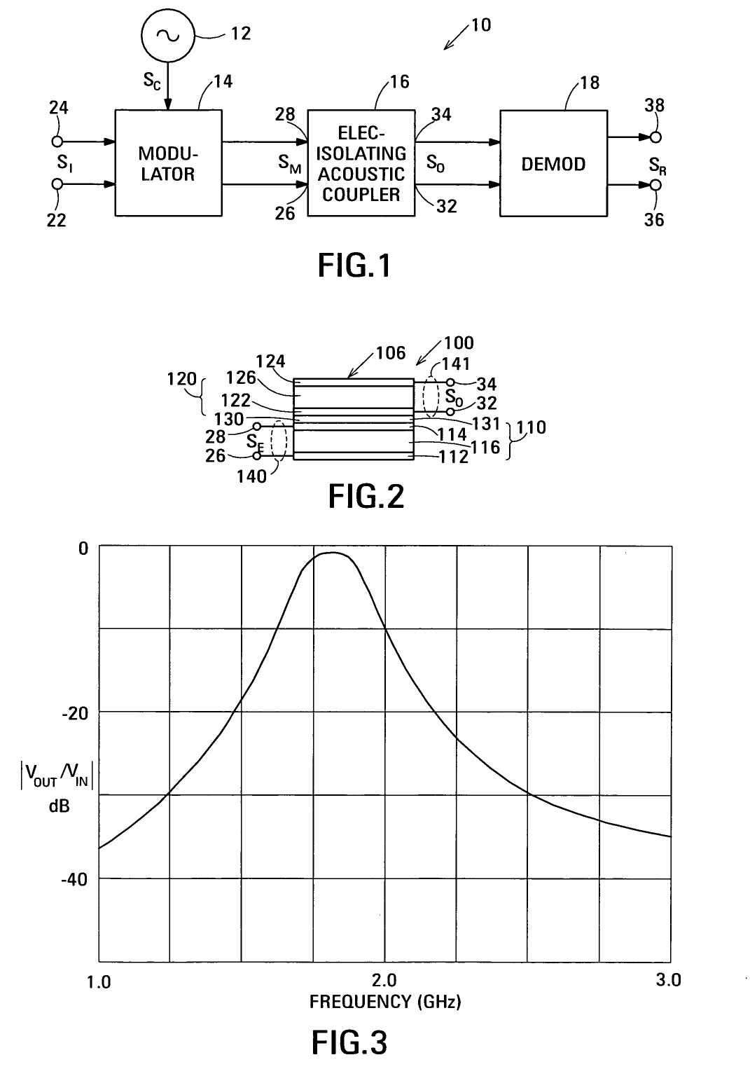

FIG. 1 is a block diagram showing an acoustic galvanic isolator 10 in accordance with an embodiment of the invention. Acoustic galvanic isolator 10 transmits an electrical information signal S₁ between its input terminals and its output terminals yet provides electrical isolation between its input terminals and its output terminals. Acoustic galvanic isolator 10 not only provides electrical isolation at DC but additionally provides a.c. electrical isolation. Electrical information signal S₁ is typically a high data rate digital data signal, but may alternatively be an analog signal. In one application, electrical information signal S₁ is a 100 Mbit/sec Ethernet signal.

In the example shown, acoustic galvanic isolator 10 is composed of a local oscillator 12, a modulator 14, an electrically-isolating acoustic coupler 16 and a demodulator 18. In the example shown, local oscillator 12 is the source of an electrical carrier signal S_{C}. Modulator 14 has inputs connected to receive electrical information signal S₁ from the input terminals 22, 24 of acoustic galvanic isolator 10 and to receive carrier signal S_{C} from local oscillator 12. Modulator 14 has outputs connected to inputs 26, 28 of electrically-isolating acoustic coupler 16.

Outputs 32, 34 of electrically-isolating acoustic coupler 16 are connected to the inputs of demodulator 18. The outputs of demodulator 18 are connected to output terminals 36, 38 of acoustic galvanic isolator 10.

Electrically-isolating acoustic coupler 16 has a band-pass frequency response that will be described in more detail below with reference to FIG. 3. Local oscillator 12 generates carrier signal S_{C} at a frequency nominally at the center of the pass band of electrically-isolating acoustic coupler 16. In one exemplary embodiment of acoustic galvanic isolator 10, the pass band of electrically-isolating acoustic coupler 16 is centered at a frequency of 1.9 GHz, and local oscillator 12 generated carrier signal S_{C} at a frequency of 1.9 GHz. Local oscillator 12 feeds carrier signal S_{C} to the carrier signal input of modulator 14.

Modulator 14 receives electrical information signal S₁ from input terminals 22, 24 and modulates carrier signal S_{C} with electrical information signal S₁ to generate modulated electrical signal S_{M}. Typically, modulated electrical signal S_{M} is carrier signal S_{C} amplitude modulated in accordance with electrical information signal S₁. Any suitable modulation scheme may be used. In an example in which carrier signal S_{C} is amplitude modulated by electrical information signal S₁ and electrical information signal S₁ is a digital signal having low and high signal levels respectively representing 0s and 1s, modulated electrical signal S_{M} has small and large amplitudes respectively representing the 0s and 1s of the electrical information signal.

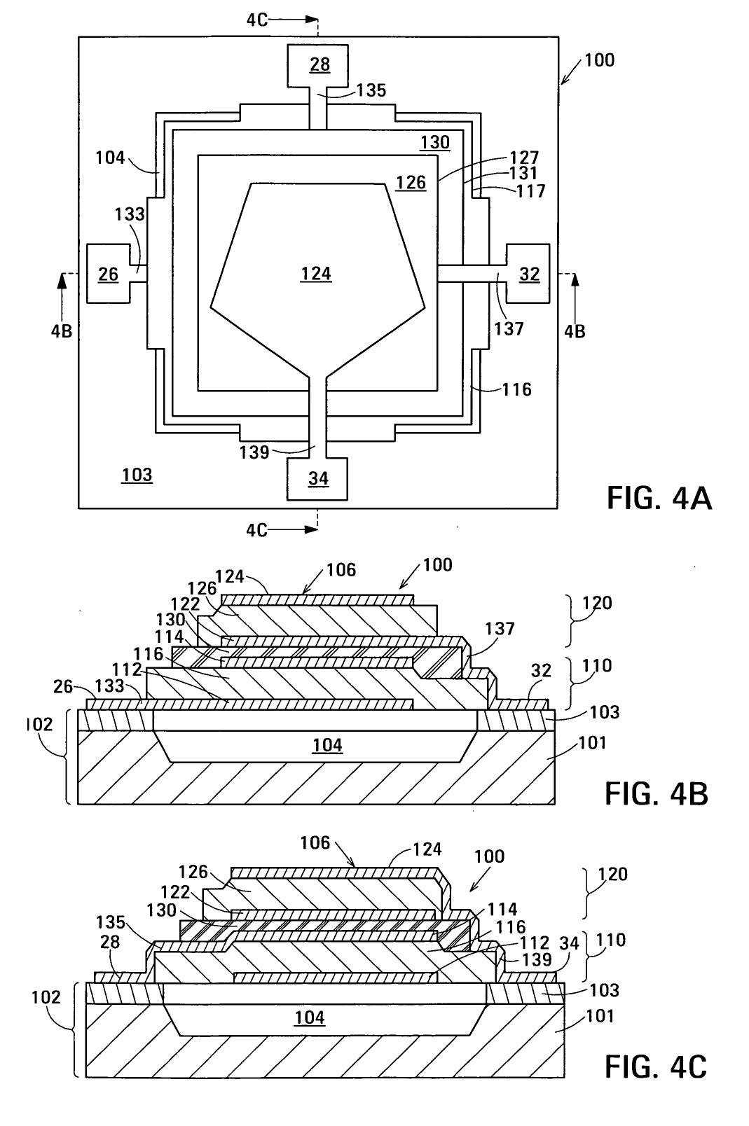

As will be described in more detail below with reference to FIGS. 2 and 4A-4C, electrically-isolating acoustic coupler 16 acoustically couples modulated electrical signal S_{M} from its inputs 26, 28 to its outputs 32, 34 to provide an electrical output signal S_{O} to the inputs of demodulator 18. Electrical output signal S_{O} is similar to modulated electrical signal S_{M}, i.e., it is a modulated electrical signal having the same frequency as carrier signal S_{C}, the same modulation scheme as modulated electrical signal S_{M} and the same information content as electrical information signal S₁. Demodulator 18 demodulates electrical output signal S_{O} to recover electrical information signal S₁ as recovered electrical information signal S_{R}. Recovered electrical information signal S_{R} is output from demodulator 18 to output terminals 36, 38.

Demodulator 18 comprises a detector (not shown) that recovers electrical information signal S₁ from electrical output signal S_{O} as is known in the art. In an example, the detector rectifies and integrates electrical output signal S_{O} to recover electrical information signal S₁. Typically, in an embodiment intended for applications in which electrical information signal S₁ is a digital signal, demodulator 18 additionally includes a clock and data recovery (CDR) circuit following the detector. The CDR circuit operates to clean up the waveform of the raw electrical information signal recovered from the electrical output signal S_{O} to generate recovered electrical information signal S_{R}. Demodulator 18 provides the recovered electrical information signal S_{R} to the output terminals 36, 38 of acoustic galvanic isolator 10.

Circuits suitable for use as local oscillator 12, modulator 14 and demodulator 18 of acoustic galvanic isolator 10 are known in the art. Consequently, local oscillator 12, modulator 14 and demodulator 18 will not be described in further detail.

In the embodiment shown in FIG. 1, local oscillator 12 is shown as part of acoustic galvanic isolator 10. In other embodiments, instead of a local oscillator, acoustic galvanic isolator 10 has carrier signal input terminals (not shown) via which the acoustic galvanic isolator receives the carrier signal S_{C} from an external carrier signal generator. In such embodiments, the carrier signal input terminals provide the carrier signal source for the acoustic galvanic isolator.

Acoustic couplers in according with embodiments of the invention that can be used as electrically-isolating acoustic coupler 16 in acoustic galvanic isolator 10 will now be described. Such embodiments all have a band-pass frequency response, as will be described in more detail below with reference to FIG. 3. The pass-band of the acoustic coupler is characterized by a center frequency and a bandwidth. The bandwidth of the pass-band determines the maximum data rate of the information signal that can be acoustically coupled by the acoustic coupler. For simplicity, the center frequency of the pass band of the acoustic coupler will be referred to as the center frequency of the acoustic coupler. As will be described further below, the acoustic coupler embodiments are composed in part of layers of various acoustically-transmissive materials whose thickness depends on the wavelength in the acoustically-transmissive material of an acoustic signal nominally equal in frequency to the center frequency of the acoustic coupler. In acoustic galvanic isolator 10 shown in FIG. 1, the frequency of carrier signal S_{C} is nominally equal to the center frequency of the pass band of the acoustic coupler used as electrically-isolating acoustic coupler 16.

In this disclosure, the term quarter-wave layer will be used to denote a layer of acoustically-transmissive material having a nominal thickness t equal to an odd integral multiple of one quarter of the wavelength in the material of an acoustic signal nominally equal in frequency to the center frequency of the acoustic coupler, i.e.:
t≈(2m+1)λₙ/4 (1)
where λₙ is the wavelength of the above-mentioned acoustic signal in the acoustically-transmissive material and m is an integer equal to or greater than zero. The thickness of a quarter-wave layer may differ from the nominal thickness by approximately ±10% of λₙ/4. A thickness outside this tolerance range can be used with some degradation in performance, but the thickness of a quarter-wave layer always differs significantly from an integral multiple of πₙ/2.

Moreover, in this disclosure, a quarter wave layer having a thickness equal to a specific number of quarter wavelengths of the above-mentioned acoustic signal in the material of the layer will be denoted by preceding the term quarter-wave layer by a number denoting the number of quarter wavelengths. For example, the term one quarter-wave layer will be used to denote a layer of acoustically-transmissive material having a nominal thickness t equal to one quarter of the wavelength in the material of an acoustic signal equal in frequency to the center frequency of the acoustic coupler, i.e., t≈λₙ/4 (m=0 in equation (1)). A one quarter-wave layer is a quarter-wave layer of a least-possible thickness. Similarly, a three quarter-wave layer has a nominal thickness t equal to three quarter wavelengths of the above-mentioned acoustic signal, i.e., t≈3λₙ/4 (m=1 in equation (1)).

The term half-wave layer will be used to denote a layer of acoustically-transmissive material having a nominal thickness t equal to an integral multiple of one half of the wavelength in the material of an acoustic signal equal in frequency to the center frequency of the acoustic coupler, i.e.:
t≈nλₙ/2 (2)
where n is an integer greater than zero. The thickness of a half-wave layer may differ from the nominal thickness by approximately ±10% of λₙ/2. A thickness outside this tolerance range can be used with some degradation in performance, but the thickness of a half-wave layer always differs significantly from an odd integral multiple of λₙ/4. The term half-wave layer may be preceded with a number to denote a layer having a thickness equal to a specific number of half wavelengths of the above-mentioned acoustic signal in the material of the layer.

Acoustic galvanic isolators and their constituent electrically-isolating acoustic couplers are characterized by a breakdown voltage. The breakdown voltage of an acoustic galvanic isolator is the voltage that, when applied between the input terminals and output terminals of the acoustic galvanic isolator, causes a leakage current greater than a threshold leakage current to flow. In acoustic galvanic isolators with multiple input terminals and multiple output terminals, as in this disclosure, the input terminals are electrically connected to one another and the output terminals are electrically connected to one another to make the breakdown voltage measurement. The breakdown voltage of an electrically-isolating acoustic coupler is the voltage that, when applied between the inputs and outputs of the acoustically-resonant electrical insulator, causes a leakage current greater than a threshold leakage current to flow. In electrically-isolating acoustic couplers with multiple inputs and multiple outputs, as in this disclosure, the inputs are electrically connected to one another and the outputs are electrically connected to one another to make the breakdown voltage measurement. The threshold leakage current is application-dependent, and is typically of the order of microamps.

2. Acoustic Coupler Embodiments Based on Single DSBAR

FIG. 2 is a schematic diagram showing an example of an acoustic coupler 100 in accordance with a first embodiment of the invention. Acoustic coupler 100 comprises a single decoupled stacked bulk acoustic resonator (DSBAR) 106, inputs 26, 28, outputs 32, 34, an electrical circuit 140 that connects DSBAR 106 to inputs 26, 28 and an electrical circuit 141 that connects DSBAR 106 to outputs 32, 34. DSBAR 106 incorporates an electrically-insulating acoustic decoupler 130 that provides electrical isolation between inputs 26, 28 and outputs 32, 34.

When used as electrically-isolating acoustic coupler 16 in acoustic galvanic isolator 10 shown in FIG. 1, acoustic coupler 100 acoustically couples modulated electrical signal S_{M} from inputs 26, 28 to outputs 32, 34 while providing electrical isolation between inputs 26, 28 and outputs 32, 34. Thus, acoustic coupler 100 effectively galvanically isolates output terminals 36, 38 from input terminals 22, 24, and allows the output terminals to differ in voltage from the input terminals by a voltage up to its specified breakdown voltage.

DSBAR 106 is composed of a lower film bulk acoustic resonator (FBAR) 110, an upper FBAR 120 stacked on FBAR 110, and an electrically-insulating acoustic decoupler 130 between lower FBAR 110 and upper FBAR 120. FBAR 110 is composed of opposed planar electrodes 112 and 114 and a piezoelectric element 116 between the electrodes. FBAR 120 is composed of opposed planar electrodes 122 and 124 and a piezoelectric element 126 between the electrodes. Acoustic decoupler 130 is located between electrode 114 of FBAR 110 and electrode 122 of FBAR 120.

Electrical circuit 140 electrically connects electrodes 112 and 114 of FBAR 110 to inputs 26, 28, respectively. Electrical circuit 141 electrically connects electrodes 122 and 124 of FBAR 120 to outputs 32, 34, respectively. Modulated electrical signal S_{M} received at inputs 26, 28 applies a voltage between electrodes 112 and 114 of FBAR 110. FBAR 110 converts the modulated electrical signal S_{M} to an acoustic signal. Specifically, the voltage applied to piezoelectric element 116 by electrodes 112 and 114 mechanically deforms piezoelectric element 116, which causes FBAR 110 to vibrate mechanically at the frequency of the modulated electrical signal. Electrically-insulating acoustic coupler 130 couples part of the acoustic signal generated by FBAR 110 to FBAR 120. Additionally, electrically-insulating acoustic decoupler 130 is electrically insulating and therefore electrically isolates FBAR 120 from FBAR 110m, and, hence, inputs 26, 28 from outputs 32, 34. FBAR 120 receives the acoustic signal coupled by acoustic decoupler 130 and converts the acoustic signal back into an electrical signal that appears across piezoelectric element 126. The electrical signal is picked up by electrodes 122 and 124 and is fed to outputs 32, 34, respectively, as electrical output signal S_{O}. Electrical output signal S_{O} appearing between outputs 32, 34 has the same frequency as, and includes the information content of, the modulated electrical signal S_{M} applied between inputs 26, 28. Thus, acoustic coupler 100 effectively acoustically couples the modulated electrical signal S_{M} from inputs 26, 28 to outputs 32, 34.

Acoustic decoupler 130 controls the coupling of the acoustic signal generated by FBAR 110 to FBAR 120 and, hence, the bandwidth of acoustic coupler 100. Specifically, due to a substantial mis-match in acoustic impedance between the acoustic decoupler and FBARs 110 and 120, the acoustic decoupler couples less of the acoustic signal from FBAR 110 to FBAR 120 than would be coupled by direct contact between the FBARs.

FIG. 3 shows the frequency response characteristic of an exemplary embodiment of DSBAR 106. DSBAR 106 exhibits a flat in-band response with a pass bandwidth of greater than 100 MHz, which is sufficiently broad to transmit the full bandwidth of an embodiment of modulated electrical signal S_{M} resulting from modulating carrier signal S_{C} with an embodiment of electrical information signal S₁ having a data rate greater than 100 Mbit/s. The frequency response of DSBAR 106 additionally exhibits a sharp roll-off outside the pass band.

FIG. 4A is a plan view showing a practical example of acoustic coupler 100. FIGS. 4B and 4C are cross-sectional views along section lines 4B-4B and 4C-4C, respectively, shown in FIG. 4A. The same reference numerals are used to denote the elements of acoustic coupler 100 in FIG. 3 and in FIGS. 4A-4C.

In the embodiment of acoustic coupler 100 shown in FIGS. 4A-4C, DSBAR 106 is suspended over a cavity 104 defined in a substrate 102. Suspending DSBAR 106 over a cavity allows the stacked FBARs 110 and 120 constituting DSBAR 106 to resonate mechanically in response to modulated electrical signal S_{M}. Other suspension schemes that allow the stacked FBARs to resonate mechanically are possible. For example, DSBAR 106 can be acoustically isolated from substrate 102 by an acoustic Bragg reflector (not shown), as described by John D. Larson III et al. in United States patent application publication no. 2005 0 104 690 entitled Cavity-Less Film Bulk Acoustic Resonator (FBAR) Devices, assigned to the assignee of this disclosure and incorporated by reference.

In the example shown in FIGS. 4A-4C, the material of substrate 102 is single-crystal silicon. Since single-crystal silicon is a semiconductor and is therefore not a good electrical insulator, substrate 102 is typically composed of a base layer 101 of single crystal silicon and an insulating layer 103 of a dielectric material located on the major surface of the base layer. Exemplary materials of the insulating layer include aluminum nitride, silicon nitride, polyimide, a crosslinked polyphenylene polymer and any other suitable electrically-insulating material. Insulating layer 103 insulates DSBAR 106 from base layer 101. Alternatively, the material of substrate 102 can be a ceramic material, such as alumina, that has a very high electrical resistivity and breakdown field.

In the example shown in FIGS. 4A-4C, a piezoelectric layer 117 of piezoelectric material provides piezoelectric element 116 and a piezoelectric layer 127 of piezoelectric material provides piezoelectric element 126. Additionally, an acoustic decoupling layer 131 of acoustic decoupling material provides acoustic decoupler 130.

In the example of acoustic coupler 100 shown in FIGS. 4A-4C, inputs 26, 28 shown in FIG. 2 are embodied as terminal pads 26, 28 located on the major surface of substrate 102. Electrical circuit 140 shown in FIG. 2 is composed of an electrical trace 133 that extends from terminal pad 26 to electrode 112 of FBAR 110 and an electrical trace 135 that extends from terminal pad 28 to electrode 114 of FBAR 110. Electrical trace 133 extends over part of the major surface of substrate 102 and under part of piezoelectric element 116 and electrical trace 135 extends over part of the major surface of substrate 102 and over part of piezoelectric element 116. Outputs 32, 34 are embodied as terminal pads 32 and 34 located on the major surface of substrate 102. Electrical circuit 141 shown in FIG. 2 is composed of an electrical trace 137 that extends from terminal pad 32 to electrode 122 of FBAR 120 and an electrical trace 139 that extends from terminal pad 34 to electrode 124 of FBAR 120. Electrical trace 137 extends over parts of the major surfaces of acoustic decoupler 130, piezoelectric element 116 and substrate 102. Electrical trace 139 extends over parts of the major surfaces of piezoelectric element 126, acoustic decoupler 130, piezoelectric element 116 and substrate 102.

In embodiments in which local oscillator 12, modulator 14 and demodulator 18 are fabricated in and on substrate 102, terminal pads 26, 28, 32 and 34 are typically omitted and electrical traces 133 and 135 are extended to connect to corresponding traces constituting part of modulator 14 and electrical traces 137 and 139 are extended to connect to corresponding traces constituting part of demodulator 18.

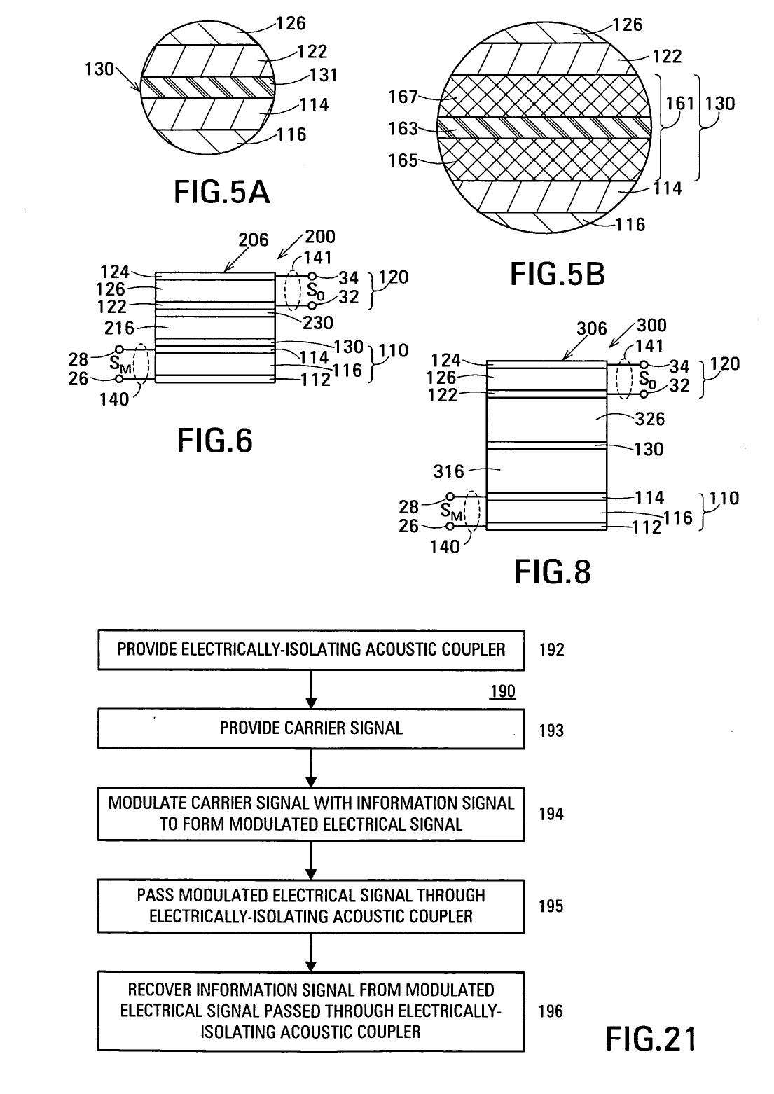

FIG. 5A is an enlarged view of the portion marked 5A in FIG. 4B showing a first embodiment of electrically-insulating acoustic decoupler 130. In the embodiment shown in FIG. 5A, acoustic decoupler 130 is composed of an acoustic decoupling layer 131 of electrically-isolating acoustic decoupling material located between the electrode 114 of FBAR 110 and electrode 122 of FBAR 120. The acoustic decoupling material of acoustic decoupling layer 131 has an acoustic impedance intermediate between that of air and that of the materials of FBARs 110 and 120, and additionally has a high electrical resistivity and a high breakdown field.

The acoustic impedance of a material is the ratio of stress to particle velocity in the material and is measured in Rayleighs, abbreviated as rayl. The piezoelectric material of the piezoelectric elements 116 and 126 of FBARs 110 and 120, respectively is typically aluminum nitride (AlN) and the material of electrodes 112, 114, 122 and 124 is typically molybdenum (Mo). The acoustic impedance of AlN is typically about 35 Mrayl and that of molybdenum is about 63 Mrayl. The acoustic impedance of air is about 1 krayl.

Typically, the acoustic impedance of the electrically-isolating acoustic decoupling material of acoustic decoupling layer 131 is about one order of magnitude less that of the piezoelectric material that constitutes the piezoelectric elements 116 and 126 of FBARs 110 and 120, respectively. The bandwidth of the pass band of acoustic coupler 100 depends on the difference in acoustic impedance between the acoustic decoupling material of acoustic decoupling layer 131 and the materials of FBARs 110 and 120. In embodiments of acoustic decoupler 100 in which the materials of FBARs 110 and 120 are as stated above, acoustic decoupling materials with an acoustic impedance in the range from about 2 Mrayl to about 8 Mrayl will result in acoustic decoupler having a pass bandwidth sufficient to allow acoustic galvanic isolator 10 (FIG. 1) to operate at data rates greater than 100 Mb/s.

In the embodiment of acoustic decoupler 130 shown in FIG. 5A, acoustic decoupling layer 131 is a quarter-wave layer. For a given acoustic decoupling material, the electrical breakdown field of the acoustic decoupling material of acoustic decoupling layer 131 and the thickness of acoustic decoupling layer 131 are the main factors that determine the breakdown voltage of acoustic coupler, and, hence, the breakdown voltage between the input terminals 22, 24 and the output terminals 36, 38 of acoustic galvanic isolator 10. However, an embodiment of acoustic coupler 100 in which the acoustic decoupling layer 131 is thicker than a one quarter-wave layer typically has a frequency response that exhibits spurious response artifacts due to the ability of such a thicker acoustic decoupling layer to support multiple acoustic modes. The spurious response artifacts tend to reduce the opening of the “eye” of the electrical output signal S_{O} output by acoustic coupler 100. To ensure the accuracy of the recovered electrical information signal S_{R} output by acoustic galvanic isolator 10 (FIG. 1), embodiments in which acoustic coupler 100 has a layer thicker than a one quarter-wave layer as acoustic decoupling layer 131 typically need a more sophisticated type of clock and data recovery circuit in demodulator 18 than embodiments in which acoustic coupler 100 has a one quarter-wave layer (m=0) as acoustic decoupling layer 131. Embodiments of acoustic coupler 100 in which acoustic decoupling layer 131 is a one quarter wave layer couple modulated electrical signal S_{M} from inputs 26, 28 to outputs 32, 34 with optimum signal integrity.

In some embodiments, acoustic decoupling layer 131 is formed by spin coating a liquid precursor for the acoustic decoupling material over electrode 114. An acoustic decoupling layer formed by spin coating will typically have regions of different thickness due to the contouring of the surface coated by the acoustic decoupling material. In such embodiment, the thickness of acoustic decoupling layer 131 is the thickness of the portion of the acoustic decoupling layer located between electrodes 114 and 122.

Many materials are electrically insulating, have high breakdown fields and have acoustic impedances in the range stated above. Additionally, many such materials can be applied in layers of uniform thickness in the thickness ranges stated above. Such materials are therefore potentially suitable for use as the acoustic decoupling material of acoustic decoupling layer 131 of acoustic decoupler 130. However, the acoustic decoupling material must also be capable of withstanding the high temperatures of the fabrication operations performed after acoustic decoupling layer 131 has been deposited on electrode 114 to form acoustic decoupler 130. In practical embodiments of acoustic coupler 100, electrodes 122 and 124 and piezoelectric layer 126 are deposited by sputtering after the acoustic decoupling material has been deposited. Temperatures as high as 400° C. are reached during these deposition processes. Thus, a material that remains stable at such temperatures is used as the acoustic decoupling material.

Typical acoustic decoupling materials have a very high acoustic attenuation per unit length compared with the materials of FBARs 110 and 120. However, since the above-described embodiment of electrically-insulating acoustic decoupler 130 is composed of acoustic decoupling layer 131 of acoustic decoupling material typically less than 1 μm thick, the acoustic attenuation introduced by acoustic decoupling layer 131 of acoustic decoupling material is typically negligible.

In one embodiment, a polyimide is used as the acoustic decoupling material of acoustic decoupling layer 131. Polyimide is sold under the trademark Kapton® by E.I. du Pont de Nemours and Company. In such embodiment, acoustic decoupler 130 is composed of acoustic decoupling layer 131 of polyimide applied to electrode 114 by spin coating. Polyimide has an acoustic impedance of about 4 Mrayl and a breakdown field of about 165 kV/mm.

In another embodiment, a poly(para-xylylene) is used as the acoustic decoupling material of acoustic decoupling layer 131. In such embodiment, acoustic decoupler 130 is composed of acoustic decoupling layer 131 of poly(para-xylylene) applied to electrode 114 by vacuum deposition. Poly(para-xylylene) is also known in the art as parylene. The dimer precursor di-para-xylylene from which parylene is made and equipment for performing vacuum deposition of layers of parylene are available from many suppliers. Parylene has an acoustic impedance of about 2.8 Mrayl and a breakdown field of about 275 kV/mm.

In another embodiment, a crosslinked polyphenylene polymer is used as the acoustic decoupling material of acoustic decoupling layer 131. In such embodiment, acoustic decoupler 130 is composed of acoustic decoupling layer 131 of a crosslinked polyphenylene polymer the precursor solution for which is applied to electrode 114 by spin coating. Crosslinked polyphenylene polymers have been developed as low dielectric constant dielectric materials for use in integrated circuits and consequently remain stable at the high temperatures to which the acoustic decoupling material is subject during the subsequent fabrication of FBAR 120. Crosslinked polyphenylene polymers additionally have a calculated acoustic impedance of about 2 Mrayl. This acoustic impedance is in the range of acoustic impedances that provides acoustic coupler 100 with a pass bandwidth sufficient for operation at data rates of over 100 Mbit/s.

Precursor solutions containing various oligomers that polymerize to form respective crosslinked polyphenylene polymers are sold by The Dow Chemical Company, Midland, Mich., under the registered trademark SiLK. The precursor solutions are applied by spin coating. The crosslinked polyphenylene polymer obtained from one of these precursor solutions designated SiLK™ J, which additionally contains an adhesion promoter, has a calculated acoustic impedance of 2.1 Mrayl, i.e., about 2 Mrayl. This crosslinked polyphenylene polymer has a breakdown field of about 400 kV/mm.

The oligomers that polymerize to form crosslinked polyphenylene polymers are prepared from biscyclopentadienone- and aromatic acetylene-containing monomers. Using such monomers forms soluble oligomers without the need for undue substitution. The precursor solution contains a specific oligomer dissolved in gamma-butyrolactone and cyclohexanone solvents. The percentage of the oligomer in the precursor solution determines the layer thickness when the precursor solution is spun on. After application, applying heat evaporates the solvents, then cures the oligomer to form a cross-linked polymer. The biscyclopentadienones react with the acetylenes in a 4+2 cycloaddition reaction that forms a new aromatic ring. Further curing results in the cross-linked polyphenylene polymer. The above-described crosslinked polyphenylene polymers are disclosed by Godschalx et al. in U.S. Pat. No. 5,965,679, incorporated herein by reference. Additional practical details are described by Martin et al., Development of Low-Dielectric Constant Polymer for the Fabrication of Integrated Circuit Interconnect, 12 ADVANCED MATERIALS, 1769 (2000), also incorporated by reference. Compared with polyimide, crosslinked polyphenylene polymers are lower in acoustic impedance, lower in acoustic attenuation, lower in dielectric constant and higher in breakdown field. Moreover, a spun-on layer of the precursor solution is capable of producing a high-quality film of the crosslinked polyphenylene polymer with a thickness of the order of 200 nm, which is a typical thickness of acoustic decoupling layer 131.

In an alternative embodiment, the acoustic decoupling material of acoustic decoupling layer 131 providing acoustic decoupler 130 is an electrically-insulating material whose acoustic impedance is substantially greater than that of the materials of FBARs 110 and 120. No materials having this property are known at this time, but such materials may become available in future, or lower acoustic impedance FBAR materials may become available in future. The thickness of acoustic decoupling layer 131 of such high acoustic impedance acoustic decoupling material is as described above.

FIG. 5B is an enlarged view of the portion marked 5A in FIG. 4B showing a second embodiment of electrically-insulating acoustic decoupler 130. In the embodiment shown in FIG. 5B, acoustic decoupler 130 is composed of an electrically-insulating acoustic Bragg structure 161. Electrically-insulating acoustic Bragg structure 161 comprises a low acoustic impedance Bragg element 163 located between high acoustic impedance Bragg elements 165 and 167. At least one of the Bragg elements 163, 165 and 167 of Bragg structure 161 comprises a layer of material having a high electrical resistivity, a low dielectric permittivity and a high breakdown field. Low acoustic impedance Bragg element 163 is a quarter-wave layer of a low acoustic impedance material whereas high acoustic impedance Bragg elements 165 and 167 are each a quarter-wave layer of high acoustic impedance material. The acoustic impedances of the materials of the Bragg elements are characterized as “low” and “high” with respect to one another and with respect to the acoustic impedance of the piezoelectric material of piezoelectric elements 116 and 126.

In one embodiment, low acoustic impedance Bragg element 163 is a quarter-wave layer of silicon dioxide (SiO₂), which has an acoustic impedance of about 13 Mrayl, and each of the high acoustic impedance Bragg elements 165 and 167 is a quarter-wave layer of the same material as electrodes 114 and 122, respectively, e.g., molybdenum, which has an acoustic impedance of about 63 Mrayl. Using the same material for high acoustic impedance Bragg element 165 and electrode 114 of FBAR 110 allows high acoustic impedance Bragg element 165 additionally to serve as electrode 114.

In an example, high acoustic impedance Bragg elements 165 and 167 are one quarter-wave layers of molybdenum, and low acoustic impedance Bragg element 163 is a one quarter-wave layer of SiO₂. In an embodiment in which the frequency of carrier signal S_{C} is about 1.9 MHz, molybdenum high acoustic impedance Bragg elements 165 and 167 have a thickness of about 820 nm and SiO₂ low acoustic impedance Bragg element 163 has a thickness of about 260 nm.

An alternative material for low acoustic impedance Bragg element 163 is a crosslinked polyphenylene polymer such as the above-mentioned crosslinked polyphenylene polymer made from a precursor solution sold under the registered trademark SiLK by Dow Chemical Co. Examples of alternative electrically-insulating materials for low acoustic impedance Bragg element 163 include zirconium oxide (ZrO₂), hafnium oxide (HfO), yttrium aluminum garnet (YAG), titanium dioxide (TiO₂) and various glasses. Alternative materials for high impedance Bragg elements 165 and 167 include such metals as titanium (Ti), niobium (Nb), ruthenium (Ru) and tungsten (W).

In the example just described, only one of the Bragg elements 163, 165 and 167 is insulating, and the breakdown voltage of acoustic coupler 100, and, hence, of acoustic galvanic isolator 10, is determined by the thickness of low acoustic impedance Bragg element 163 and the breakdown field of the material of low acoustic impedance Bragg element 163.

The breakdown voltage of acoustic coupler 100 can be increased by making all the Bragg elements 163, 165 and 167 constituting Bragg structure 161 of electrically-insulating material. In an exemplary embodiment, high acoustic impedance Bragg elements 163 and 167 are each a quarter-wave layer of silicon dioxide and low impedance Bragg element 165 is a quarter-wave layer of a crosslinked polyphenylene polymer, such as the above-mentioned crosslinked polyphenylene polymer made from a precursor solution sold under the registered trademark SiLK by Dow Chemical Co. However, silicon dioxide has a relatively low breakdown field of about 30 kV/mm, and a quarter-wave layer of a typical crosslinked polyphenylene polymer is relatively thin due to the relatively low velocity of sound of this material. In another all-insulating embodiment of Bragg structure 161 having a substantially greater breakdown voltage, high acoustic impedance Bragg elements 163 and 167 are each a quarter-wave layer of aluminum oxide (Al₂O₃) and low impedance Bragg element 165 is a quarter-wave layer of silicon dioxide. Aluminum oxide has an acoustic impedance of about 44 Mrayl and a breakdown field of several hundred kilovolts/mm. Additionally, the velocity of sound in aluminum oxide is about seven times higher than in a typical crosslinked polyphenylene polymer. A given voltage applied across two quarter-wave layers of aluminum oxide and a quarter wave layer of silicon dioxide results in a much lower electric field than when applied across two quarter-wave layers of silicon dioxide and one quarter-wave layer of a crosslinked polyphenylene polymer.

Examples of alternative electrically-insulating materials for Bragg elements 163, 165 and 167 include zirconium oxide (ZrO₂), hafnium oxide (HfO), yttrium aluminum garnet (YAG), titanium dioxide (TiO₂) and various glasses. The above examples are listed in an approximate order of descending acoustic impedance. Any of the examples may be used as the material of the high acoustic impedance Bragg layers 163, 167 provided that the acoustic impedance of the material of the low acoustic impedance Bragg layer 165 is less.

In embodiments of acoustic decoupler 130 in which the acoustic impedance difference between high acoustic impedance Bragg elements 165 and 167 and low acoustic impedance Bragg element 163 is relatively low, Bragg structure 161 may be composed of more than one (n) low acoustic impedance Bragg element interleaved with a corresponding number (n+1) of high acoustic impedance Bragg elements. For example, Bragg structure 161 may be composed of two low acoustic impedance Bragg elements interleaved with three high acoustic impedance Bragg elements. While only one of the Bragg elements need be electrically insulating, a higher breakdown voltage is obtained when more than one of the Bragg elements is electrically insulating.

Some galvanic isolators are required to have breakdown voltages greater than one kilovolt between their input terminals and output terminals. In acoustic coupler 100, acoustic decoupler 130 is the sole provider of electrical isolation between inputs 26, 28 and outputs 32, 34. Embodiments of acoustic galvanic isolator 10 in which electrically-isolating acoustic coupler 16 is embodied as acoustic coupler 100 have difficulty in meeting such voltage requirements.

Two acoustic coupler embodiments that comprise a single insulating decoupled stacked bulk acoustic resonator (IDSBAR) having one or more acoustically-resonant electrical insulators located between its constituent film bulk acoustic resonators (FBARs) will be described next. The one or more acoustically-resonant electrical insulators provide more electrical isolation between inputs 26, 28 and outputs 32, 34 than is provided by electrically-insulating acoustic decoupler 130 described above. Accordingly, the acoustic couplers to be described next have a substantially greater breakdown voltage than acoustic coupler 100 described above with reference to FIG. 2.

3. Acoustic Coupler Embodiments in Which DSBARs Comprise Acoustically-Resonant Electrical Insulators

(a) Single Quarter-Wave Acoustically-Resonant Electrical Insulator

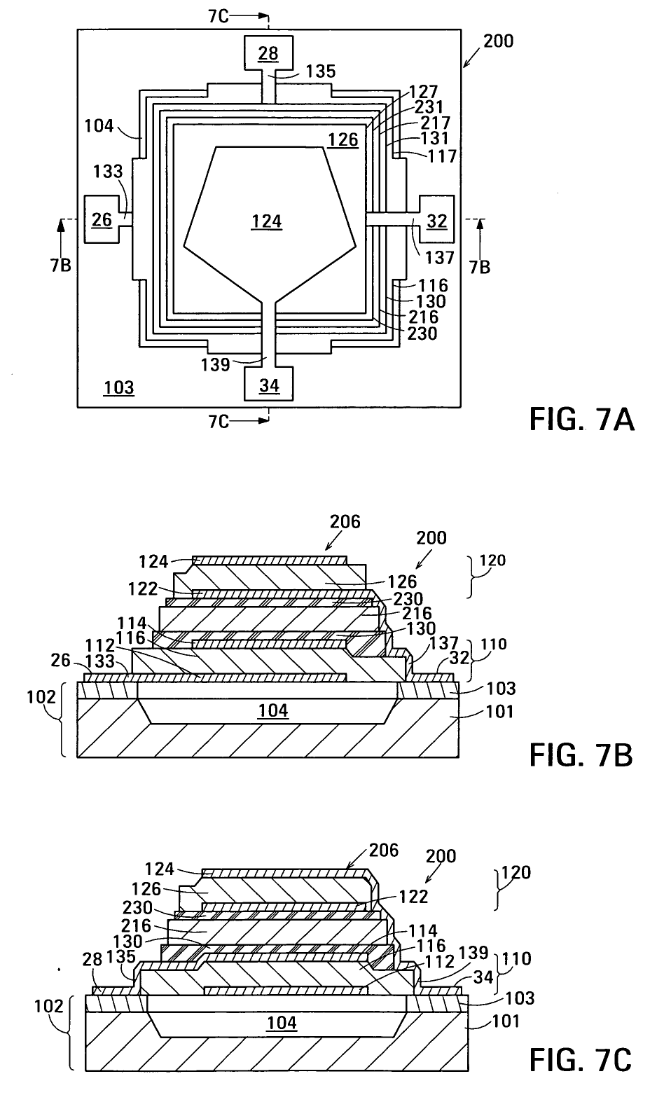

FIG. 6 is a schematic diagram showing an example of an acoustic coupler 200 in accordance with a second embodiment of the invention. FIG. 7A is a plan view showing a practical example of acoustic coupler 200. FIGS. 7B and 7C are cross-sectional views along section lines 7B-7B and 7C-7C, respectively, shown in FIG. 7A. The same reference numerals are used to denote the elements of acoustic coupler 200 in FIG. 6 and in FIGS. 7A-7C. Acoustic coupler 200 comprises inputs 26, 28, outputs 32, 34, and an insulated decoupled stacked bulk acoustic resonator (IDSBAR) 206 in accordance with a first IDSBAR embodiment. In its simplest form, an IDSBAR in accordance with the first IDSBAR embodiment has a first acoustic decoupler, a quarter-wave acoustically-resonant electrical insulator and a second acoustic decoupler in order between its constituent FBARs. IDSBAR 206 in accordance with the first IDSBAR embodiment gives acoustic coupler 200 a substantially greater breakdown voltage than acoustic coupler 100 described above with reference to FIG. 2. In the example shown in FIG. 6, acoustic coupler 200 additionally comprises electrical circuit 140 that connects IDSBAR 206 to inputs 26, 28, and electrical circuit 141 that connects IDSBAR 206 to outputs 32, 34.

When used as electrically-isolating acoustic coupler 16 in acoustic galvanic isolator 10 shown in FIG. 1, acoustic coupler 200 acoustically couples modulated electrical signal S_{M} from inputs 26, 28 to outputs 32, 34 while providing electrical isolation between inputs 26, 28 and outputs 32, 34. Thus, acoustic coupler 200 effectively galvanically isolates output terminals 36, 38 from input terminals 22, 24, and allows the output terminals to differ in voltage from the input terminals by a voltage up to its specified breakdown voltage.

In the exemplary embodiment of acoustic coupler 200 shown in FIGS. 6 and 7A-7C, IDSBAR 206 comprises a lower film bulk acoustic resonator (FBAR) 110, an upper film bulk acoustic resonator 120 stacked on FBAR 110 and, located in order between lower FBAR 110 and upper FBAR 120, first acoustic decoupler 130, a quarter-wave acoustically-resonant electrical insulator 216 and a second acoustic decoupler 230.

In acoustic coupler 200, first acoustic decoupler 130 couples part of the acoustic signal generated by FBAR 110 to acoustically-resonant electrical insulator 216 and second acoustic decoupler 230 couples part of the acoustic signal from acoustically-resonant electrical insulator 216 to FBAR120. Additionally, at least one of first acoustic decoupler 130, acoustically-resonant electrical insulator 216 and second acoustic decoupler 230 electrically isolates inputs 26, 28 from outputs 32, 34. In embodiments of IDSBAR 206 in which acoustic decouplers 130 and 230 are not electrically insulating, acoustically-resonant electrical insulator 216 is the sole provider of electrical isolation between inputs 26, 28 and outputs 32, 34. In other embodiments of IDSBAR 206, at least one of acoustic decouplers 130 and 230 is electrically insulating and provides additional electrical isolation. In further embodiments of IDSBAR 206, two or more (n) acoustically-resonant electrical insulators interleaved with a corresponding number (n+1) of acoustic decouplers are located between FBARs 110 and 120.

FBARs 110 and 120, first acoustic decoupler 130, electrical circuits 140 and 141 and substrate 102 are described above with reference to FIGS. 2 and 4A-4C and will not be described again here. The description of first acoustic decoupler 130 set forth above additionally applies to second acoustic decoupler 230. Accordingly, second acoustic decoupler 230 will not be individually described. The exemplary embodiments of acoustic decoupler 130 described above with reference to FIGS. 5A and 5B may be used to provide each of first acoustic decoupler 130 and second acoustic decoupler 230. In the example shown in FIGS. 7A-7C, an acoustic decoupling layer 131 of acoustic decoupling material provides first acoustic decoupler 130 and an acoustic decoupling layer 231 of acoustic decoupling material provides second acoustic decoupler 230.

Acoustically-resonant electrical insulator 216 is a quarter-wave layer of electrically-insulating material. Embodiments of acoustic coupler 200 in which acoustically-resonant electrical insulator 216 is a one quarter-wave layer typically couple modulated electrical signal S_{M} from inputs 26, 28 to outputs 32, 34 with optimum signal integrity.

The electrically-insulating material of acoustically-resonant electrical insulator 216 is typically a dielectric or piezoelectric material matched in acoustic impedance to FBARs 110 and 120. For example, acoustically-resonant electrical insulator 216 may be fabricated from the same material as piezoelectric elements 116 and 126 of FBARs 110 and 120 respectively. In embodiments in which the material of acoustically-resonant electrical insulator 216 differs from that of piezoelectric elements 116 and 126, the difference in acoustic impedance is substantially less than one order of magnitude. In an example, the acoustic impedances have a ratio of less than two. The material of acoustically-resonant electrical insulator 216 differs from that of piezoelectric elements 116 and 126 in an embodiment in which the material of acoustically-resonant electrical insulator 216 is a dielectric, for example. Suitable dielectric materials for acoustically-resonant electrical insulator 216 include aluminum oxide (Al₂O₃) and non-piezoelectric (ceramic) aluminum nitride (AlN).

Although acoustically-resonant electrical insulator 216 is optimally a one quarter-wave layer, the velocity of sound in the typical piezoelectric and dielectric materials of acoustically-resonant electrical insulator 216 is substantially higher than in typical materials of acoustic decouplers 130 and 230. Consequently, an acoustically-resonant electrical insulator 216 that is a one quarter-wave layer of aluminum nitride, for example, has a thickness about seven times that of a one quarter-wave layer of a typical acoustic decoupling material. As a result, a given voltage between inputs 26, 28 and outputs 32, 34 produces a much lower electric field when applied across such an embodiment of acoustically-resonant electrical insulator 216 than when applied across acoustic decoupler 130 of acoustic coupler 100 shown in FIG. 2. Additionally, the breakdown field of a typical material of acoustically-resonant electrical insulator 216 is typically comparable with that of a typical acoustic decoupling material. Consequently, acoustic coupler 200 typically has a greater breakdown voltage than acoustic coupler 100 shown in FIG. 2.

In the example shown in FIGS. 7A-7C, a piezoelectric layer 117 of piezoelectric material provides piezoelectric element 116 and a piezoelectric layer 127 of piezoelectric material provides piezoelectric element 126. Additionally, an acoustic decoupling layer 131 of acoustic decoupling material provides first acoustic decoupler 130, an acoustic decoupling layer 231 of acoustic decoupling material provides second acoustic decoupler 230, and a layer 217 of electrically-insulating material provides acoustically-resonant electrical insulator 216.

In acoustic coupler 200, first acoustic decoupler 130 controls the coupling of the acoustic signal generated by FBAR 110 to acoustically-resonant electrical insulator 216 and second acoustic decoupler 230 controls the coupling of the acoustic signal from acoustically-resonant electrical insulator 216 to FBAR 120. Acoustic decouplers 130 and 230 collectively define the bandwidth of acoustic coupler 200. Specifically, due to the substantial mis-match in acoustic impedance between first acoustic decoupler 130 on one hand and FBAR 110 and acoustically-resonant electrical insulator 216 on the other hand, acoustic decoupler 130 couples less of the acoustic signal generated by FBAR 110 to acoustically-resonant electrical insulator 216 than would be coupled by direct contact between the FBAR 110 and acoustically-resonant electrical insulator 216. Similarly, due to the substantial mis-match in acoustic impedance between second acoustic decoupler 230 on one hand and acoustically-resonant electrical insulator 216 and FBAR 120 on the other hand, acoustic decoupler 230 couples less acoustic of the acoustic signal from acoustically-resonant electrical insulator 216 to FBAR 120 than would be coupled by direct contact between acoustically-resonant electrical insulator 216 and FBAR 120. The two acoustic decouplers 130 and 230 cause acoustic coupler 200 to have a somewhat narrower bandwidth than acoustic coupler 100 described above with reference to FIG. 2, which has a single acoustic decoupler 130.

(b) Two Half-wave Acoustically-Resonant Electrical Insulators

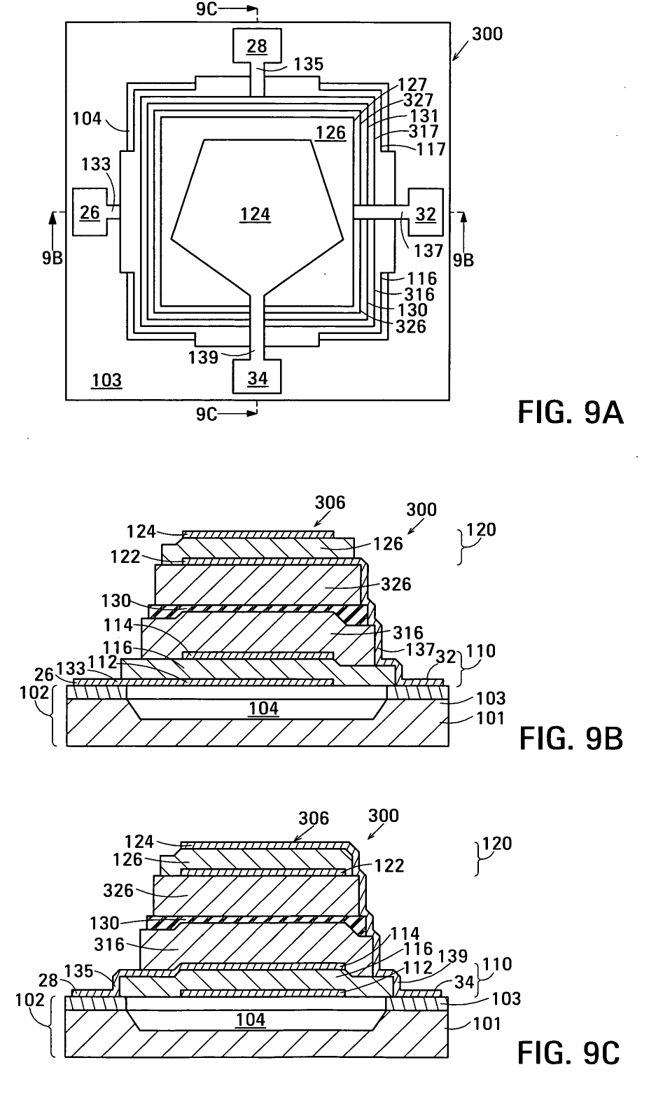

FIG. 8 is a schematic diagram showing an example of an acoustic coupler 300 in accordance with a third embodiment of the invention. FIG. 9A is a plan view showing a practical example of acoustic coupler 300. FIGS. 9B and 9C are cross-sectional views along section lines 9B-9B and 9C-9C, respectively, shown in FIG. 9A. The same reference numerals are used to denote the elements of acoustic coupler 300 in FIG. 8 and in FIGS. 9A-9C.

Acoustic coupler 300 comprises inputs 26, 28, outputs 32, 34, and an insulated stacked bulk acoustic resonator (IDSBAR) 306 in accordance with a second IDSBAR embodiment. In its simplest form, an IDSBAR in accordance with the second IDSBAR embodiment has a first half-wave acoustically-resonant electrical insulator, an acoustic decoupler and a second half-wave acoustically-resonant electrical insulator located in order between its constituent FBARs. IDSBAR 306 in accordance with the second IDSBAR embodiment gives acoustic coupler 300 a substantially greater breakdown voltage than acoustic coupler 100 described above with reference to FIG. 2 and acoustic coupler 200 described above with reference to FIGS. 6 and 7A-7C. In the example shown, acoustic coupler 300 additionally comprises electrical circuit 140 that connects IDSBAR 306 to inputs 26, 28 and electrical circuit 141 that connects IDSBAR 306 to outputs 32, 34.

When used as electrically-isolating acoustic coupler 16 in acoustic galvanic isolator 10 shown in FIG. 1, acoustic coupler 300 acoustically couples modulated electrical signal S_{M} from inputs 26, 28 to outputs 32, 34 while providing electrical isolation between inputs 26, 28 and outputs 32, 34. Thus, acoustic coupler 300 effectively galvanically isolates output terminals 36, 38 from input terminals 22, 24, and allows the output terminals to differ in voltage from the input terminals by a voltage up to its specified breakdown voltage.

In acoustic decoupler 300, insulated decoupled stacked bulk acoustic resonator (IDSBAR) 306 has a first half-wave acoustically-resonant electrical insulator 316, an acoustic decoupler 130 and a second half-wave acoustically-resonant electrical insulator 326 located in order between its FBARs. Half-wave acoustically-resonant electrical insulators 316 and 326 provide additional electrical insulation between inputs 26, 28 and outputs 32, 34 without impairing the signal integrity of the modulated electrical signal S_{M} acoustically coupled from inputs 26, 28 to outputs 32, 34. Moreover, half-wave acoustically-resonant electrical insulators 316 and 326 are two in number and are twice as thick as quarter-wave acoustically-resonant electrical insulator 216 described above with reference to FIG. 6. Half-wave acoustically-resonant electrical insulators 316 and 326 therefore collectively provide approximately four times the electrical isolation provided by quarter-wave acoustically-resonant electrical insulator 216. As a result, embodiments of acoustic coupler 300 have a greater breakdown voltage between inputs 26, 28 and outputs 32, 34 than otherwise similar embodiments of acoustic coupler 200 described above with reference to FIG. 6.

In the exemplary embodiment of acoustic coupler 300 shown in FIGS. 8 and 9A-9C, IDSBAR 306 comprises lower film bulk acoustic resonator (FBAR) 110, upper film bulk acoustic resonator 120 stacked on FBAR 110 and, located in order between lower FBAR 110 and upper FBAR 120, half-wave acoustically-resonant electrical insulator 316, acoustic decoupler 130 and half-wave acoustically-resonant electrical insulator 326.

Half-wave acoustically-resonant electrical insulator 316, acoustic decoupler 130 and half-wave acoustically-resonant electrical insulator 326 collectively couple the acoustic signal generated by FBAR 110 to FBAR 120 and electrically isolate inputs 26, 28 from outputs 32, 34. In embodiments of IDSBAR 306 in which acoustic decoupler 130 is not electrically insulating, acoustically-resonant electrical insulators 316 and 316 are the sole providers of electrical isolation between inputs 26, 28 and outputs 32, 34. In other embodiments of IDSBAR 306, acoustic decoupler 130 is also electrically insulating and provides some additional electrical isolation between inputs 26, 28 and outputs 32, 34. In further embodiments of IDSBAR 306, an even number (2n) of half-wave acoustically-resonant electrical insulators interleaved with a corresponding number (2n−1) of acoustic decouplers is located between the FBARs 110 and 120.

FBARs 110 and 120, acoustic decoupler 130, electrical circuits 140 and 141 and substrate 102 are described above with reference to FIGS. 2 and 4A-4C and will not be described again here. The exemplary embodiments of acoustic decoupler 130 described above with reference to FIGS. 5A and 5B may be used to provide acoustic decoupler 130.

Half-wave acoustically-resonant electrical insulator 316 will now be described. The following description also applies to half-wave acoustically-resonant electrical insulator 326. Therefore, acoustically-resonant electrical insulator 326 will not be individually described. Acoustically-resonant electrical insulator 316 is a half-wave layer of electrically-insulating material that is nominally matched in acoustic impedance to FBARs 110 and 120. Embodiments in which half-wave acoustically-resonant electrical insulator 316 is a one half-wave layer typically couple modulated electrical signal S_{M} from inputs 26, 28 to outputs 32, 34 with optimum signal integrity.

At the center frequency of acoustic coupler 300, half-wave acoustically-resonant electrical insulator 316 and half-wave acoustically-resonant electrical insulator 326 are acoustically transparent. Half-wave acoustically-resonant electrical insulator 316 couples the acoustic signal generated by FBAR 110 to acoustic decoupler 130 and half-wave acoustically-resonant electrical insulator 326 couples the acoustic signal transmitted by acoustic decoupler 130 to FBAR 120. Thus, IDSBAR 306 has signal coupling characteristics similar to those of DSBAR 106 described above with reference to FIG. 2. Additionally, half-wave acoustically-resonant electrical insulators 316 and 326 electrically insulate FBAR 120 from FBAR 110 and acoustic decoupler 130 typically provides additional electrical insulation as described above. Thus, acoustic coupler 300 effectively acoustically couples the modulated electrical signal S_{M} from inputs 26, 28 to outputs 32, 34 but electrically isolates outputs 32, 34 from inputs 26, 28.

The materials described above with reference to FIG. 6 as being suitable for use as quarter-wave acoustically-resonant electrical insulator 216 are suitable for use as half-wave acoustically-resonant electrical insulators 316 and 326. The materials of half-wave acoustically-resonant electrical insulators 316 and 326 will therefore not be further described.

Half-wave acoustically-resonant electrical insulators 316 and 326 are each many times the thickness of acoustic decoupler 130 and are each twice as thick as quarter-wave acoustically-resonant electrical insulator 216 described above with reference to FIG. 6. Moreover, two half-wave acoustically-resonant electrical insulators 316 and 326 separate FBAR 120 from FBAR 110. As a result, a given voltage between inputs 26, 28 and outputs 32, 34 produces a much lower electric field when applied across half-wave acoustically-resonant electrical insulators 316 and 326 and acoustic decoupler 130 than when applied exclusively across electrically-insulating acoustic decoupler 130 in the embodiment of acoustic coupler 100 described above with reference to FIG. 2 or than when applied across acoustic decouplers 130 and 230 and quarter-wave acoustically-resonant electrical insulator 216 in the embodiment of acoustic coupler 200 described above with reference to FIG. 6. Consequently, acoustic coupler 300 typically has a substantially greater breakdown voltage than both acoustic coupler 100 and acoustic coupler 200.

In the example shown in FIGS. 9A-9C, a piezoelectric layer 117 of piezoelectric material provides piezoelectric element 116 and a piezoelectric layer 127 of piezoelectric material provides piezoelectric element 126. Additionally, a half-wave layer 317 of electrically-insulating material provides half-wave acoustically-resonant electrical insulator 316, an acoustic decoupling layer 131 of acoustic decoupling material provides acoustic decoupler 130, and a half-wave layer 327 of electrically-insulating material provides half-wave acoustically-resonant electrical insulator 326.

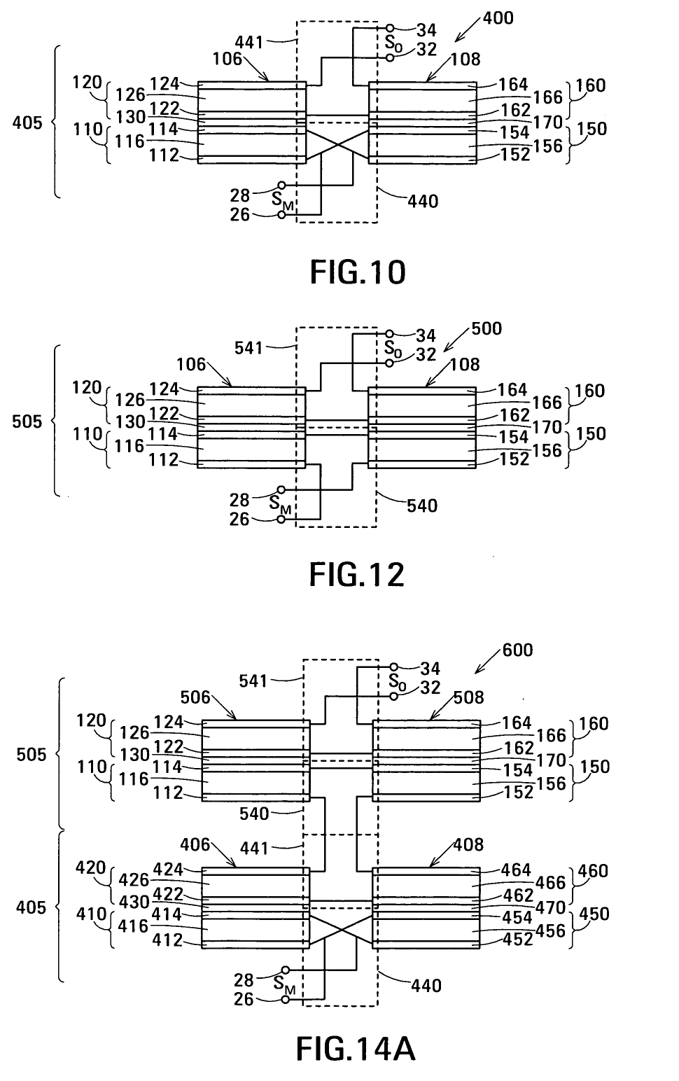

Referring again to FIG. 1, in addition to providing galvanic isolation between input terminals 22, 24 and output terminals 36, 38, in some applications, an embodiment of acoustic galvanic isolator 10 that additionally provides common mode rejection between input terminals 22, 24 and output terminals 36, 38 is desirable. With an embodiment of acoustic galvanic isolator 10 that provides common mode rejection, a signal that is present on both inputs 22, 24 appears in a highly attenuated form between output terminals 36, 38. Acoustic coupler embodiments that can be used as electrically-isolating acoustic coupler 16 and that additionally provide common mode rejection will be described next with reference to FIGS. 10, 11A-11C, 12, 13A-13C, 14A, 14B and 15. Moreover, in such acoustic coupler embodiments, one of the piezoelectric elements additionally provides at least part of the electrical isolation between inputs 26, 28 and outputs 32, 34, so that the acoustic coupler embodiments have a higher breakdown voltage than the above-described acoustic coupler embodiments having the same number of constituent layers.

4. Acoustic Coupler Embodiments Based on Film Acoustically-Coupled Transformers

(a) Acoustic Coupler Based on Antiparallel-Series FACT

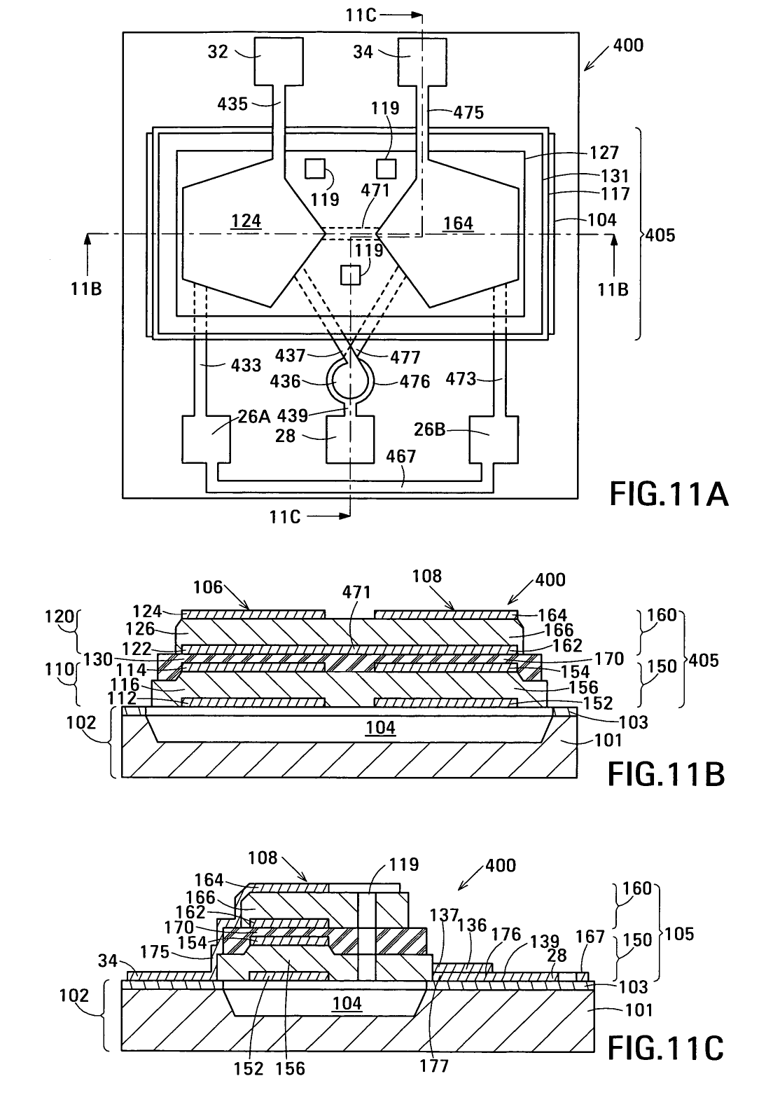

FIG. 10 is a schematic diagram showing an example of an acoustic coupler 400 in accordance with a fourth embodiment of the invention. FIG. 11A is a plan view of a practical example of acoustic coupler 400. FIGS. 11B and 11C are cross-sectional views along section lines 11B-11B and 11C-11C, respectively, in FIG. 11A. The same reference numerals are used to denote the elements of acoustic coupler 400 in FIG. 10 and in FIGS. 11A-11C.

Acoustic coupler 400 comprises inputs 26, 28, outputs 32, 34, and an electrically-isolating film acoustically-coupled transformer (FACT) 405 electrically connected between the inputs and the outputs. FACT 405 is composed of a first decoupled stacked bulk acoustic resonator (DSBAR) 106 and a second DSBAR 108, an electrical circuit 440 that interconnects DSBAR 106 and DSBAR 108 and that additionally connects DSBARs 106 and 108 to inputs 26, 28, and an electrical circuit 441 that interconnects DSBAR 106 and DSBAR 108 and that additionally connects DSBARs 106 and 108 to outputs 32, 34. In electrically-isolating FACT 405, the piezoelectric element of one of the film bulk acoustic resonators (FBARs) of each of the DSBARs 106 and 108 provides at least part of the electrical isolation between inputs 26, 28 and outputs 32, 34.

When used as electrically-isolating acoustic coupler 16 in acoustic galvanic isolator 10 shown in FIG. 1, acoustic coupler 400 acoustically couples modulated electrical signal S_{M} from inputs 26, 28 to outputs 32, 34 while providing electrical isolation between inputs 26, 28 and outputs 32, 34. Thus, acoustic coupler 400 effectively galvanically isolates output terminals 36, 38 from input terminals 22, 24, and allows the output terminals to differ in voltage from the input terminals by a voltage up to its specified breakdown voltage.

In electrically-isolating FACT 400, each DSBAR 106, 108 is composed of a stacked pair of film bulk acoustic resonators (FBARs) and an acoustic decoupler between the FBARs. DSBAR 106 and its constituent FBARs 110, 120 are described above with reference to FIGS. 2 and 4A-4C. DSBAR 108 is composed of a lower FBAR 150, an upper FBAR 160 stacked on FBAR 150, and an acoustic decoupler 170 between lower FBAR 150 and upper FBAR 160. In some embodiments, acoustic decouplers 130 and 170 are electrically insulating and provide additional electrical isolation.

FBAR 150 is composed of opposed planar electrodes 152 and 154 and a piezoelectric element 156 between the electrodes. FBAR 160 is composed of opposed planar electrodes 162 and 164 and a piezoelectric element 166 between the electrodes. Acoustic decoupler 170 is located between electrode 154 of FBAR 150 and electrode 162 of FBAR 160.

Electrical circuit 440 electrically connects FBAR 110 of DSBAR 106 in anti-parallel with FBAR 150 of DSBAR 108 and to inputs 26 and 28. Specifically, electrical circuit 440 electrically connects electrode 112 of FBAR 110 to electrode 154 of FBAR 150 and to input 26 and additionally electrically connects electrode 114 of FBAR 110 to electrode 152 of FBAR 150 and to input 28. Electrical circuit 441 electrically connects FBAR 120 of DSBAR 106 and FBAR 160 of DSBAR 108 in series between outputs 32 and 34. Specifically, electrical circuit 441 connects output 32 to electrode 124 of FBAR 120, electrode 122 of FBAR 120 to electrode 162 of FBAR 160 and electrode 164 of FBAR 160 to output 34.

Electrical circuit 440 electrically connects FBARs 110 and 150 in anti-parallel so that it applies modulated electrical signal S_{M} received at inputs 26, 28 to FBARs 110 and 150 equally but in antiphase. FBARs 110 and 150 convert modulated electrical signal S_{M} to respective acoustic signals. Electrical circuit 440 electrically connects FBARs 110 and 150 in anti-parallel such that it applies modulated electrical signal S_{M} to FBAR 110 in a sense that causes FBAR 110 to contract mechanically whereas it applies modulated electrical signal S_{M} to FBAR 150 in a sense that causes FBAR 150 to expand mechanically by the same amount, and vice versa. The acoustic signal generated by FBAR 150 is therefore in antiphase with the acoustic signal generated by FBAR 110. Consequently, the acoustic signal received by FBAR 160 from FBAR 150 is in antiphase with the acoustic signal received by FBAR 120 from FBAR 110. FBARs 120 and 160 convert the acoustic signals they receive back to respective electrical signals. The electrical signal generated by FBAR 160 is in antiphase with the electrical signal generated by FBAR 120. Electrical circuit 441 connects FBARs 120 and 160 in series such that the voltages across the FBARs add, and the voltage difference between electrodes 124 and 164 and, hence between outputs 32, 34, is twice the voltage across each of FBARs 120 and 160. The electrical output signal S_{O} appearing between outputs 32, 34 has the same frequency as, and includes the information content of, the modulated electrical signal S_{M} applied between inputs 26, 28. Thus, acoustic coupler 400 effectively acoustically couples the modulated electrical signal S_{M} from inputs 26, 28 to outputs 32, 34.

In acoustic coupler 400, at least piezoelectric elements 126 and 166 electrically isolate outputs 32, 34 from inputs 26, 28. Typical piezoelectric elements have a high electrical resistivity and breakdown field. For example, samples of sputter-deposited aluminum nitride have a measured breakdown field of about 875 kV/mm. Moreover, in typical embodiments of acoustic coupler 400 in which acoustic decouplers 130 and 170 are electrically insulating, acoustic decouplers 130 and 170 are in series with piezoelectric elements 126 and 166, respectively, and provide additional electrical isolation.

Substantially the same capacitance exists between each of the inputs 26, 28 and substrate 102. Each of the inputs 26, 28 has connected to it one electrode adjacent substrate 102 and one electrode separated from substrate 102 by a respective piezoelectric element. In the example shown, input 26 is connected to electrode 112 adjacent the substrate and electrode 154 separated from the substrate by piezoelectric element 156, and input 28 is connected to electrode 152 adjacent the substrate and electrode 114 separated from the substrate by piezoelectric element 116. Moreover, substantially the same capacitance exists between each of the outputs 32, 34 and substrate 102. Outputs 32, 34 are connected to electrodes 124 and 164, each of which is separated from the substrate by two piezoelectric elements and an acoustic decoupler. Thus, acoustic coupler 400 is electrically balanced and, as a result, has a high common-mode rejection ratio.

In acoustic coupler 400, acoustic decoupler 130 controls the coupling of the acoustic signal generated by FBAR 110 to FBAR 120 as described above with reference to FIG. 2. Acoustic decoupler 170 controls the coupling of the acoustic signal generated by FBAR 150 to FBAR 160 in a similar manner. Acoustic couplers 130 and 170 control the bandwidth of acoustic coupler 400. Acoustic coupler 400 has a frequency response characteristic similar to that described above with reference to FIG. 3 and, in particular has a flat in-band response that is sufficiently broad to transmit the full bandwidth of an embodiment of modulated electrical signal S_{M} resulting from modulating an approximately 1.9 GHz carrier signal S_{C} with an embodiment of electrical information signal S₁ having a data rate greater than 100 Mbit/s. The frequency response of acoustic coupler 400 additionally exhibits a sharp roll-off outside the pass band.

In the embodiment of acoustic coupler 400 shown in FIGS. 11A-11C, DSBAR 106 and DSBAR 108 constituting FACT 405 are suspended over common cavity 104 defined in substrate 102. Suspending DSBARs 106 and 108 over cavity 104 allows the stacked FBARs 110 and 120 constituting DSBAR 106 and the stacked FBARs 150 and 160 constituting DSBAR 108 to resonate mechanically in response to modulated electrical signal S_{M}. Substrate 102 is described above with reference to FIGS. 4A-4C.

Other suspension schemes that allow DSBARs 106 and 108 to resonate mechanically are possible. For example, DSBAR 106 and DSBAR 108 may be suspended over respective cavities (not shown) defined in substrate 102. In another example, DSBAR 106 and DSBAR 108 are acoustically isolated from substrate 102 by an acoustic Bragg reflector (not shown), as described above with reference to FIGS. 2 and 4A-4C.

In the example shown in FIGS. 11A-11C, a piezoelectric layer 117 of piezoelectric material provides piezoelectric elements 116 and 156 and a piezoelectric layer 127 of piezoelectric material provides piezoelectric elements 126 and 166. Additionally, in the example shown in FIGS. 11A-11C, a single acoustic decoupling layer 131 of acoustic decoupling material provides acoustic decouplers 130 and 170.

In the example shown in FIGS. 11A-11C, input 26 shown in FIG. 10 is embodied as terminal pads 26A and 26B, and input 28 shown in FIG. 10 is embodied as a terminal pad 28. Terminal pads 26A, 26B and 28 are located on the major surface of substrate 102. Electrical circuit 440 shown in FIG. 10 is composed of an electrical trace 433 that extends from terminal pad 26A to electrode 112 of FBAR 110, an electrical trace 473 that extends from terminal pad 26B to electrode 154 of FBAR 150, and an electrical trace 467 that extends between terminal pads 26A and 26B. Additionally, a connection pad 476, an electrical trace 439 that extends from terminal pad 28 to connection pad 476, and an electrical trace 477 that extends from connection pad 476 to electrode 152 of FBAR 150 collectively constitute the portion of electrical circuit 440 (FIG. 10) that connects electrode 152 of FBAR 150 to terminal pad 28. Electrical trace 439, a connection pad 436 in electrical contact with connection pad 476 and an electrical trace 437 extending from connection pad 436 to electrode 114 of FBAR 110 collectively constitute the portion of electrical circuit 440 (FIG. 10) that connects electrode 114 of FBAR 110 to terminal pad 28. Electrical traces 433, 437, 473 and 477 all extend over part of the major surface of substrate 102. Additionally, electrical traces 433 and 477 extend under part of piezoelectric layer 117 and electrical traces 437 and 473 extend over part of piezoelectric layer 117.

Outputs 32, 34 are embodied as terminal pads 32, 34, respectively, located on the major surface of substrate 102. Electrical circuit 441 shown in FIG. 10 is composed of an electrical trace 435 that extends from terminal pad 32 to electrode 124 of FBAR 120, an electrical trace 471 that extends from electrode 122 of FBAR 120 to electrode 162 of FBAR 160, and an electrical trace 475 that extends from terminal pad 34 to electrode 164 of FBAR 160. Electrical traces 435 and 475 each extend over parts of the major surfaces of piezoelectric layer 127, acoustic decoupling layer 131, piezoelectric layer 117 and substrate 102. Electrical trace 471 extends over parts of the major surface of acoustic decoupling layer 131.

In embodiments of acoustic galvanic isolator 10 (FIG. 1) in which local oscillator 12, modulator 14 and demodulator 18 are fabricated in and on substrate 102, terminal pads 26, 28, 32 and 34 are typically omitted and electrical traces 433, 439 and 473 are extended to connect to corresponding traces constituting part of modulator 14 and electrical traces 435 and 475 are extended to connect to corresponding traces constituting part of demodulator 18.

The breakdown voltage of acoustic coupler 400 may be increased by structuring each of DSBAR 106 and DSBAR 108 similarly to IDSBAR 206 described above with reference to FIG. 6, or similarly to IDSBAR 306 described above with reference to FIG. 8.

(b) Acoustic Coupler Based on Series-Series FACT

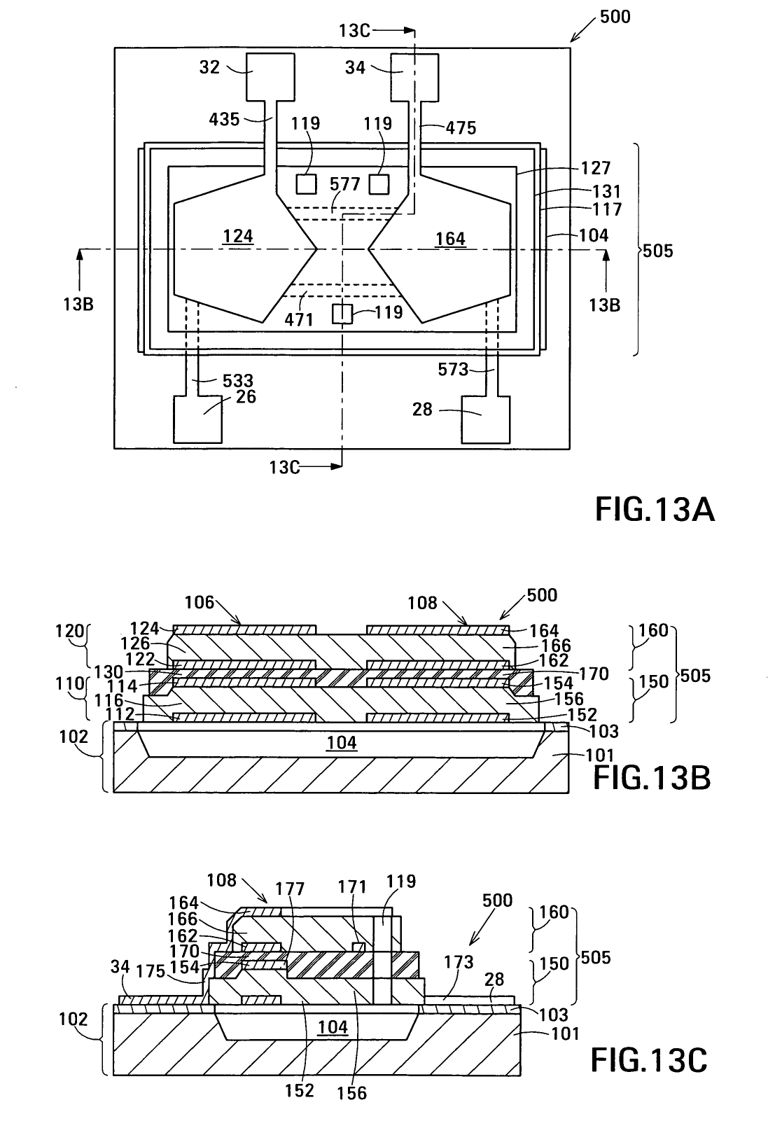

FIG. 12 is a schematic diagram showing an example of an acoustic coupler 500 in accordance with a fifth embodiment of the invention. FIG. 13A is a plan view showing the structure of an exemplary embodiment of acoustic coupler 500. FIGS. 13B and 13C are cross-sectional views along section lines 13B-13B and 13C-13C, respectively, shown in FIG. 13A. The same reference numerals are used to denote the elements of acoustic coupler 500 in FIG. 10 and in FIGS. 13A-13C. Acoustic coupler 500 has a higher breakdown voltage than acoustic coupler 400 described above with reference to FIG. 10 without additional layers.

Acoustic coupler 500 comprises inputs 26, 28, outputs 32, 34, an electrically-isolating film acoustically-coupled transformer (FACT) 505. In acoustic coupler 500, FACT 505 is composed of a first decoupled stacked bulk acoustic resonator (DSBAR) 106, a second DSBAR 108, an electrical circuit 540 that interconnects DSBAR 106 and DSBAR 108 and that additionally connects DSBARs 106 and 108 to inputs 26, 28, and an electrical circuit 541 that interconnects DSBAR 106 and DSBAR 108 and that additionally connects DSBARs 106 and 108 to outputs 32, 34. In electrically-isolating FACT 505, electrical circuit 540 connects DSBAR 106 and DSBAR 108 in series. This locates the piezoelectric element of both film bulk acoustic resonators (FBARs) of each of DSBAR 106 and DSBAR 108 in series between inputs 26, 28 and outputs 32, 34, where the piezoelectric elements provide electrical isolation. Consequently, for a given piezoelectric material and piezoelectric element thickness and for a given acoustic decoupler structure and materials, acoustic coupler 500 has a breakdown voltage similar to that of acoustic coupler 200 described above with reference to FIG. 6 but is simpler to fabricate, since it has fewer constituent layers. Acoustic coupler 500 has the same number of constituent layers as acoustic coupler 400 described above with reference to FIG. 10, but acoustic coupler 400 has a lower breakdown voltage.

When used as electrically-isolating acoustic coupler 16 in acoustic galvanic isolator 10 shown in FIG. 1, acoustic coupler 500 acoustically couples modulated electrical signal S_{M} from inputs 26, 28 to outputs 32, 34 while providing electrical isolation between inputs 26, 28 and outputs 32, 34. Thus, acoustic coupler 500 effectively galvanically isolates output terminals 36, 38 from input terminals 22, 24, and allows the output terminals to differ in voltage from the input terminals by a voltage up to its specified breakdown voltage.

In typical embodiments of acoustic coupler 500, acoustic decouplers 130 and 170 are electrically insulating, and provide additional electrical isolation. Acoustic decoupler 130 is in series with piezoelectric elements 116 and 126 and acoustic decoupler 170 is in series with piezoelectric elements 156 and 166.

DSBARs 106 and 108 are described above with reference to FIGS. 10 and 11A-11C. Electrical circuit 540 connects FBAR 110 of DSBAR 106 in series with FBAR 150 of DSBAR 108 between inputs 26, 28. Specifically, electrical circuit 540 connects input 26 to electrode 112 of FBAR 110, electrode 114 of FBAR 110 to electrode 154 of FBAR 150, and electrode 152 of FBAR 150 to input 28. Electrical circuit 541 is identical in structure to electrical circuit 441 described above with reference to FIGS. 10 and 11A-11C, and will therefore not be described again here. The arrangement of electrical circuits 540 and 541 just described connects inputs 26, 28 to electrodes 112 and 152, respectively, and outputs 32, 34 to electrodes 124 and 164, respectively. Electrodes 124 and 164 connected to outputs 32, 34 are physically separated from electrodes 112 and 152 connected to inputs 26, 28 by piezoelectric elements 116 and 156, acoustic decouplers 130 and 170 and piezoelectric elements 126 and 166. At least piezoelectric elements 116 and 156 and piezoelectric elements 126 and 166 are electrically insulating. Typically, acoustic decouplers 130 and 170 are also electrically insulating. Consequently, for similar materials and layer thicknesses, acoustic coupler 500 has a breakdown voltage similar to that of acoustic decoupler 200 described above with reference to FIG. 6, but is simpler to fabricate because it has fewer layers.

In the practical example of acoustic coupler 500 shown in FIGS. 13A-13C, inputs 26, 28 shown in FIG. 12 are embodied as terminal pads 26 and 28 located on the major surface of substrate 102. Electrical circuit 540 shown in FIG. 12 is composed of an electrical trace 533 that extends from terminal pad 26 to electrode 112 of FBAR 110, an electrical trace 577 that extends from electrode 114 of FBAR 110 to electrode 154 of FBAR 150, and an electrical trace 573 that extends from electrode 152 of FBAR 150 to terminal pad 28. Electrical traces 533 and 573 extend over part of the major surface of substrate 102 and under part of piezoelectric layer 117. Electrical trace 577 extends over part of piezoelectric layer 117.

Outputs 32, 34 are embodied as terminal pads 32 and 34 located on the major surface of substrate 102. Electrical circuit 541 has the same structure as electrical circuit 441 described above with reference to FIGS. 10 and 11A-11C and will not be described again here.

In some embodiments of acoustic galvanic isolator 10, modulator 14 is fabricated in and on the same substrate 102 as electrically-isolating acoustic coupler 16. In such embodiments, terminal pads 26, 28 are typically omitted and electrical traces 533 and 573 are extended to connect to corresponding traces constituting part of modulator 14. Additionally or alternatively, demodulator 18 is fabricated in and on the same substrate 102 as electrically-isolating acoustic coupler 16. In such embodiments, terminal pads 32, 34 are typically omitted and electrical traces 435 and 475 are extended to connect to corresponding traces constituting part of demodulator 18.

The breakdown voltage of acoustic coupler 500 may be further increased by structuring each of DSBARs 106 and 108 similarly to IDSBAR 206 described above with reference to FIG. 6, or similarly to IDSBAR 306 described above with reference to FIG. 8.

In embodiments of acoustic galvanic isolator 10 (FIG. 1) in which any one of the acoustic couplers 100, 200, 300 and 400 described above with reference to FIGS. 2, 6, 8 and 10, respectively, is used as electrically-isolating acoustic coupler 16, modulator 14 drives the inputs 26, 28 of the acoustic coupler with a single-ended modulated electrical signal S_{M}. However, modulated electrical signal S_{M} is coupled from inputs 26, 28 to outputs 32, 34 with optimum signal integrity in embodiments of acoustic galvanic isolator 10 in which acoustic coupler 400 is used as electrically-isolating acoustic coupler 16 and in which modulator 14 has a differential output circuit that drives the inputs 26, 28 of acoustic coupler 500 differentially. Differential output circuits are known in the art and will therefore not be described here.

Acoustic coupler 500 may be used as electrically-isolating acoustic coupler 16 in embodiments of acoustic galvanic isolator 10 shown in FIG. 1 in which modulator 14 has a single-ended output by interposing an additional film acoustically-coupled transformer (FACT) similar to FACT 405 described above with reference to FIG. 10 between inputs 26, 28 and FACT 505. The additional FACT converts the single-ended signal output by modulator 14 into a differential signal suitable for driving FACT 505.

(c) Acoustic Coupler Based on Series-Connected Antiparallel and Series FACTs

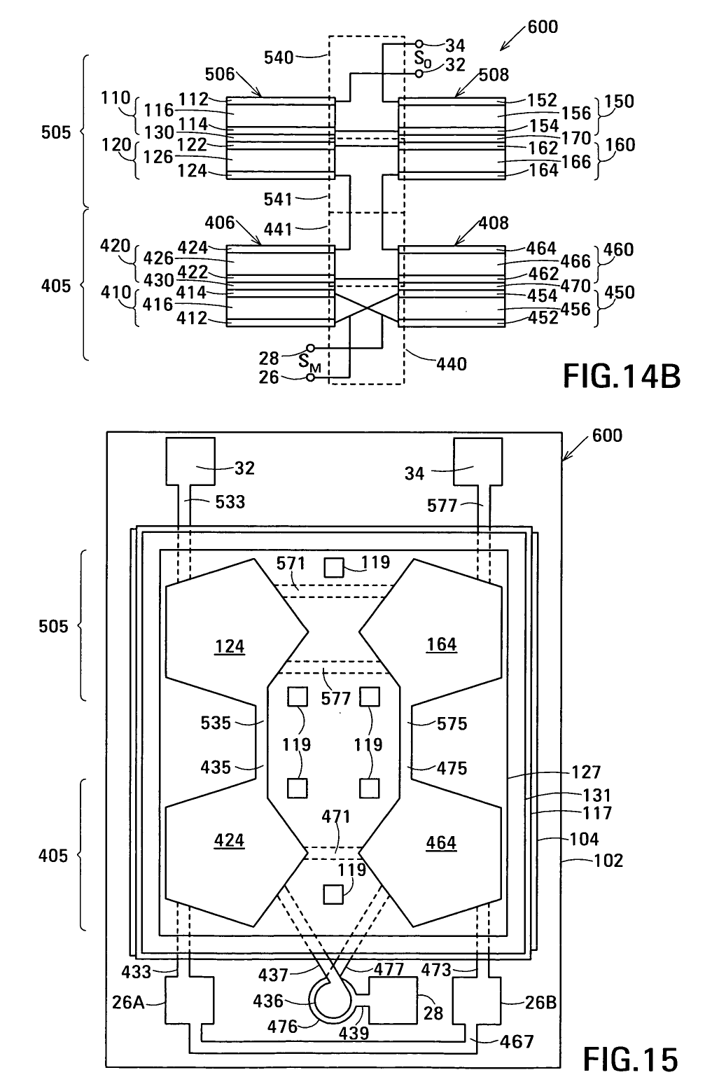

FIG. 14A is a schematic diagram showing an example of an acoustic coupler 600 in accordance with a sixth embodiment of the invention. Acoustic coupler 600 may be used as electrically-isolating acoustic coupler 16 in acoustic galvanic isolator 10 shown in FIG. 1. Acoustic coupler 600 has an additional FACT 405 interposed between inputs 26, 28 and FACT 505.

The description of FACT 405 set forth the above with reference to FIGS. 10 and 11A-11C applies to the embodiment of FACT 405 shown in FIG. 14A with the exception that the reference numerals used to indicate the elements of the latter have four instead of one as their first digit. For example FBAR 410 shown in FIG. 14A corresponds to FBAR 110 described above with reference to FIG. 10. In the embodiment of FACT 405 shown in FIG. 14A, electrical circuit 440 connects FBARs 410 and 450 in anti-parallel and to inputs 26, 28 and electrical circuit 441 connects FBARs 420 and 460 in series, all as described above with reference to FIG. 10. Anti parallel-connected FBARs 410 and 450 can be driven by an embodiment of modulator 14 (FIG. 1) having a single-ended output. Series-connected FBARs 420 and 460 generate a differential output signal suitable for driving the series-connected FBARs 110 and 150 of FACT 505. Electrical circuit 441 of FACT 405 is connected to electrical circuit 540 of FACT 505 to connect series-connected FBARs 420 and 460 of FACT 405 to series-connected FBARs 110 and 160, respectively, of FACT 505.

FACT 405 and FACT 505 may be fabricated independently of one another on separate substrates. Such independent fabrications of FACT 405 and FACT 505 would appear similar to FACT 405 shown in FIGS. 11A-11C and FACT 505 shown in FIGS. 13A-11C, respectively. With independent fabrication, electrical circuit 441 of FACT 405 is connected to electrical circuit 540 of FACT 505 by establishing electrical connections (not shown) between terminal pads 32, 34 (FIG. 11A) of FACT 405 and terminal pads 26, 28 (FIG. 13A) of FACT 505. Terminal pads 26A, 26B and 28 (FIG. 11A) of FACT 405 provide the inputs 26, 28 of acoustic coupler 600 and terminal pads 32, 34 (FIG. 13A) of FACT 505 provide the outputs 32, 34 of acoustic coupler 600. Wire bonding, flip-chip connections or another suitable connection process may be used to establish the electrical connections between electrical circuit 441 of FACT 405 and electrical circuit 540 of FACT 505.

FACT 405 and FACT 505 may alternatively be fabricated on a common substrate. In such an embodiment, electrical circuit 441 of FACT 405 may be electrically connected to electrical circuit 540 of FACT 505 as just described. However, the structure of such a common-substrate embodiment can be simplified by reversing the electrical connections to FACT 505, so that electrical circuit 541 of FACT 505 is connected to electrical circuit 441 of FACT 405 and electrical circuit 540 of FACT 505 is connected to outputs 32, 34. FIG. 14B is a schematic diagram showing an example of an embodiment of acoustic coupler 600 in accordance with the sixth embodiment of the invention in which FACTs 405 and 505 are fabricated on a common substrate. FIG. 15 is a plan view showing a practical example of such an embodiment of acoustic coupler 600. Cross sectional views of FACT 405 are shown in FIGS. 11A and 11B and cross-sectional views of FACT 505 are shown in FIGS. 13B and 13C.

In the example shown in FIGS. 14B and 15, FACT 405 and FACT 505 are fabricated suspended over a common cavity 104 defined in common substrate 102 and have common metal layers in which their electrodes and electrical traces are defined, common piezoelectric layers 117, 127 that provide their piezoelectric elements and a common acoustic decoupling layer 131 that provides their acoustic decouplers. Alternatively, FACT 405 and FACT 505 may be fabricated suspended over respective cavities (not shown) defined in a common substrate and have common metal layers, piezoelectric layers and acoustic decoupling layer. As a further alternative, FACT 405 and FACT 505 may be fabricated suspended over respective cavities (not shown) defined in a common substrate and have respective metal layers, piezoelectric layers and acoustic decoupling layers.

As noted above, the electrical connections to FACT 505 are reversed to simplify the electrical connections between FACT 405 and FACT 505. This reverses the direction of acoustic signal flow in FACT 505 compared with the example described above with reference to FIGS. 12 and 13A-13C. Consequently, the direction of acoustic signal flow in FACT 505 is opposite that in FACT 405. In the example shown in FIGS. 14B and 15, series-connected FBARs 120 and 160 in FACT 505 receive a differential electrical signal from FBARs 420 and 460, respectively, of FACT 405 and, in response thereto, generate acoustic signals that are coupled by acoustic decouplers 130 and 170, respectively, to series-connected FBARs 110 and 150, respectively. In response to the acoustic signals, FBARs 110 and 150 generate differential electrical output signal S_{O}. With the reverse signal flow in FACT 505, electrical circuit 541 of FACT 505 is electrically connected to electrical circuit 441 of FACT 405 by an electrical connection between electrical trace 435 and electrical trace 535 and an electrical connection between electrical trace 475 and electrical trace 575. Electrical traces 435 and 535 extend over part of piezoelectric layer 127 from electrode 424 of FACT 405 to electrode 124 of FACT 505 and electrical traces 475 and 575 extend over part of piezoelectric layer 127 from electrode 464 of FACT 405 to electrode 164 of FACT 505. Terminal pads 26A, 26B and terminal pad 28 connected to electrodes 412 and 452, respectively, of FACT 405 provide the inputs 26, 28 of acoustic coupler 600 and terminal pads 32, 34 connected to electrodes 112 and 152, respectively, of FACT 505 provide the outputs 32, 34 of acoustic coupler 600.

Alternatively, as noted above, FACT 405 and FACT 505 may be fabricated on a common substrate without reversing the direction of the acoustic signal in FACT 505. In this case, electrical traces 435 and 475 connected to electrodes 424 and 464, respectively, of FACT 405 are electrically connected to electrical traces 533 and 577 connected to electrodes 112 and 152, respectively, of FACT 505. Additionally, terminal pads 32, 34 connected by electrical traces 535 and 575, respectively, to electrodes 124 and 164, respectively, of FACT 505 provide the outputs 32, 34 of acoustic coupler 600.

5. Acoustic Coupler Embodiments Based on Series-Connected DSBARs

(a) DSBARs Connected in Series by Connecting FBARs in Parallel

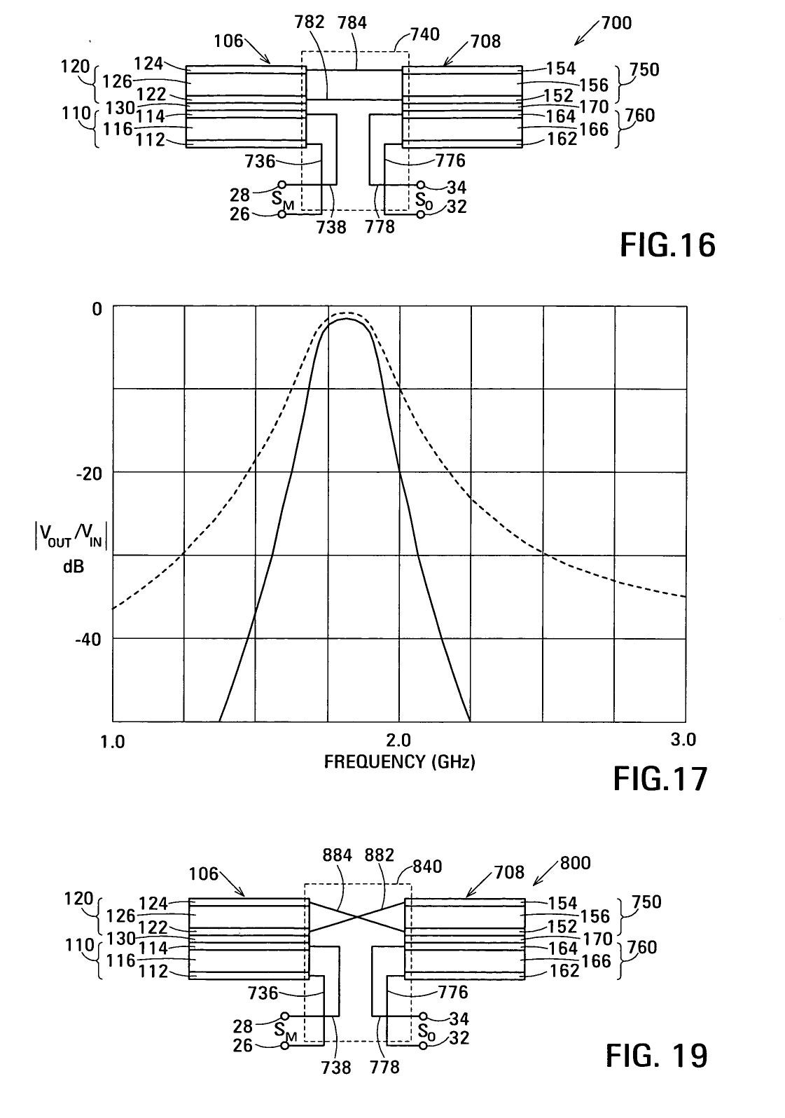

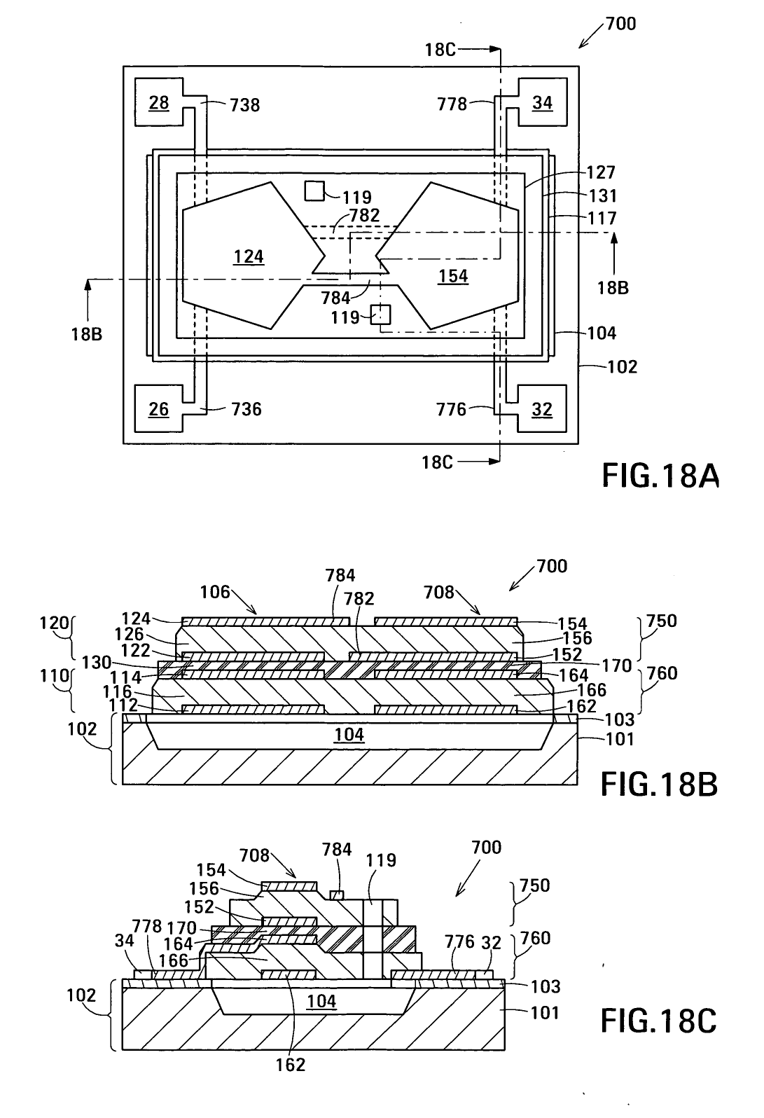

In some applications, it is desirable that the frequency response of electrically-isolating acoustic coupler 16 in acoustic galvanic isolator 10 have a sharp cut-off outside the pass-band required by modulated electrical signal S_{M}. FIG. 16 is a schematic diagram showing an example of an acoustic coupler 700 in accordance with a seventh embodiment of the invention. The frequency response of acoustic coupler 700 has a sharp cut-off outside the pass-band required by modulated electrical signal S_{M}. FIG. 18A is a plan view showing the structure of an exemplary embodiment of acoustic coupler 700. FIGS. 18B and 18C are cross-sectional views along section lines 18B-18B and 18C-18C, respectively, shown in FIG. 18A. The same reference numerals are used to denote the elements of acoustic coupler 700 in FIG. 16 and in FIGS. 18A-18C.

Acoustic coupler 700 comprises inputs 26, 28, outputs 32, 34, a first decoupled stacked bulk acoustic resonator (DSBAR) 106, a second DSBAR 708 and an electrical circuit 740 that connects DSBARs 106 and 708 in series between inputs 26, 28 and outputs 32, 34. DSBAR 106 comprises an acoustic decoupler 130 and DSBAR 708 comprises an acoustic decoupler 170. At least one of acoustic decoupler 130 and acoustic coupler 170 is electrically insulating and electrically isolates inputs 26, 28 from outputs 32, 34. Typically, acoustic decoupler 130 and acoustic coupler 170 are both electrically insulating. Electrically-insulating acoustic couplers 130 and 170 are in series between inputs 26, 28 and outputs 32, 34.

When used as electrically-isolating acoustic coupler 16 in acoustic galvanic isolator 10 shown in FIG. 1, acoustic coupler 700 acoustically couples modulated electrical signal S_{M} from inputs 26, 28 to outputs 32, 34 while providing electrical isolation between inputs 26, 28 and outputs 32, 34. Thus, acoustic coupler 700 effectively galvanically isolates output terminals 36, 38 from input terminals 22, 24, and allows the output terminals to differ in voltage from the input terminals by a voltage up to its specified breakdown voltage.

Each of DSBAR 106 and DSBAR 708 is comprises a first film bulk acoustic resonator (FBAR), a second FBAR and an acoustic decoupler between the FBARs. DSBAR 106 and its constituent FBARs 110, 120 and acoustic coupler 130 are described in detail above with reference to FIGS. 2 and 4A-4C and will not be described again here. DSBAR 708 is composed of a first FBAR 750, a second FBAR 760, and an acoustic decoupler 170 between FBAR 750 and FBAR 760. First FBAR 750 is stacked on second FBAR 760. First FBAR 750 is composed of opposed planar electrodes 152 and 154 and a piezoelectric element 156 between electrodes 152 and 154, and second FBAR 760 is composed of opposed planar electrodes 162 and 164 and a piezoelectric element 166 between electrodes 162 and 164. Acoustic decoupler 170 is located between electrode 154 of FBAR 750 and electrode 162 of FBAR 760.

In the embodiment of acoustic coupler 700 shown in FIGS. 18A-18C, DSBAR 106 and DSBAR 708 are suspended over a common cavity 104 defined in a substrate 102. Suspending DSBARs 106 and 708 over cavity 104 allows the stacked FBARs 110 and 120 constituting DSBAR 106 and the stacked FBARs 750 and 760 constituting DSBAR 708 to resonate mechanically in response to modulated electrical signal S_{M}. Substrate 102 is described above with reference to FIGS. 4A-4C.

Other suspension schemes that allow DSBAR 106 and DSBAR 708 to resonate mechanically are possible. For example, DSBAR 106 and DSBAR 708 may be suspended over respective cavities (not shown) defined in substrate 102. In another example, DSBAR 106 and DSBAR 708 are acoustically isolated from substrate 102 by an acoustic Bragg reflector (not shown), as described above with reference to FIGS. 4A-4C.

Electrical circuit 740 is composed of conductors 736, 738, 776, 778, 782 and 784. Conductors 736 and 738 respectively electrically connect inputs 26, 28 to the electrodes 112 and 114, respectively, of the first FBAR 110 of DSBAR 106. Conductors 782 and 784 connect DSBARs 106 and 708 in series by respectively connecting the electrode 122 of second FBAR 120 to the electrode 152 of first FBAR 750 and connecting the electrode 124 of second FBAR 120 to the electrode 154 of first FBAR 750. Conductors 776 and 778 respectively electrically connect the electrodes 162 and 164, respectively, of the second FBAR 760 of second DSBAR 708 to outputs 32, 34.

In the example shown in FIGS. 18A-18C, inputs 26, 28 shown in FIG. 16 are embodied as terminal pads 26, 28 respectively, and outputs 32, 34 shown in FIG. 16 are embodied as terminal pads 32, 34, respectively. Terminal pads 26, 28, 32 and 34 are located on the major surface of substrate 102. Electrical circuit 740 shown in FIG. 16 is composed of an electrical trace 736 that extends from terminal pad 26 to electrode 112 of FBAR 110, an electrical trace 738 that extends from terminal pad 28 to electrode 114 of FBAR 110, an electrical trace 782 that extends from electrode 122 of FBAR 120 to electrode 152 of FBAR 750, an electrical trace 784 that extends from electrode 124 of FBAR 120 to electrode 754 of FBAR 750, an electrical trace 776 that extends from electrode 162 of FBAR 160 to terminal pad 32 and an electrical trace 778 that extends from electrode 164 of FBAR 160 to terminal pad 34. Electrical traces 736, 738, 776 and 778 all extend over part of substrate 102. Additionally, electrical traces 736 and 776 extend under part of piezoelectric layer 117, electrical traces 738 and 778 extend over part of piezoelectric layer 117, electrical trace 782 extends over part of acoustic decoupling layer 131 and electrical trace 784 extends over part of piezoelectric layer 127.

In embodiments of acoustic galvanic isolator 10 (FIG. 1) in which local oscillator 12, modulator 14 and demodulator 18 are fabricated in and on substrate 102, terminal pads 26, 28, 32 and 34 are typically omitted and electrical traces 736 and 738 are extended to connect to corresponding traces constituting part of modulator 14 and electrical traces 776 and 778 are extended to connect to corresponding traces constituting part of demodulator 18.

In DSBAR 106, modulated electrical signal S_{M} received at inputs 26, 28 is fed via conductors 736 and 738, respectively, to the electrodes 112 and 114 of lower FBAR 110. In FBAR 110, electrodes 112 and 114 apply the electrical input signal to piezoelectric element 116. The electrical input signal applied to piezoelectric element 116 causes FBAR 110 to vibrate mechanically. Acoustic decoupler 130 couples part of the acoustic signal generated by FBAR 110 to FBAR 120 and the acoustic signal causes FBAR 120 to vibrate. The piezoelectric element 126 of FBAR 120 converts the mechanical vibration of FBAR 120 to an intermediate electrical signal that is received by the electrodes 122 and 124 of FBAR 120. Electrical circuit 740 couples the intermediate electrical signal from the electrodes 122 and 124 FBAR 120 of DSBAR 106 to the electrodes 152 and 154, respectively, of the FBAR 750 of DSBAR 708.

In DSBAR 708, FBAR 750 vibrates mechanically in response to the intermediate electrical signal applied to its piezoelectric element 156. Acoustic decoupler 170 couples part of the acoustic signal generated by FBAR 750 to FBAR 760, and the acoustic signal causes FBAR 760 to vibrate. The piezoelectric element 166 of FBAR 760 converts the mechanical vibration of FBAR 760 to an electrical output signal S_{O} that is received by the electrodes 162 and 164 of FBAR 760. Conductors 776 and 778 connect electrical output signal S_{O} from electrodes 162 and 164 to outputs 32, 34, respectively.

The electrical output signal S_{O} appearing between outputs 32, 34 has the same frequency and includes the information content of the modulated electrical signal S_{M} applied between inputs 26, 28. Thus, acoustic coupler 700 effectively acoustically couples the modulated electrical signal S_{M} from inputs 26, 28 to outputs 32, 34.

In acoustic coupler 700, at least one of acoustic decoupler 130 and acoustic coupler 170 is electrically insulating and electrically isolates inputs 26, 28 from outputs 32, 34. Typically, acoustic decoupler 130 and acoustic coupler 170 are both electrically insulating. Electrically-insulating acoustic decoupler 130 electrically insulates electrode 114 connected to input 28 from electrode 122 connected to electrode 152 and electrically-insulating acoustic decoupler 170 electrically insulates electrode 152 from electrode 164 connected to output 34. In such an embodiment, electrically-insulating acoustic decoupler 130 and electrically-insulating acoustic decoupler 170 are in series between inputs 26, 28 from outputs 32, 34 and electrically isolate inputs 26, 28 from outputs 32, 34. Thus, for a given acoustic decoupler structure and material(s), acoustic coupler 700 has a higher breakdown voltage than acoustic coupler 100 described above with reference to FIG. 2.

In acoustic coupler 700, acoustic decoupler 130 controls the coupling of the acoustic signal generated by FBAR 110 to FBAR 120 and acoustic decoupler 170 controls the coupling of the acoustic signal generated by FBAR 750 to FBAR 760, as described above. Acoustic couplers 130 and 170 collectively control the bandwidth of acoustic coupler 700. Specifically, due to a substantial mis-match in acoustic impedance between acoustic decoupler 130 and FBARs 110 and 120, acoustic decoupler 130 couples less of the acoustic signal from FBAR 110 to FBAR 120 than would be coupled by direct contact between FBARs 110 and 120. Similarly, due to a substantial mis-match in acoustic impedance between acoustic decoupler 170 and FBARs 750 and 760, acoustic decoupler 170 couples less of the acoustic signal from FBAR 750 to FBAR 760 than would be coupled by direct contact between FBARs 750 and 760.

Modulated electrical signal S_{M} is acoustically coupled through DSBARs 106 and 708 connected in series between inputs 26, 28 and outputs 32, 34. FIG. 17 shows with a broken line the frequency response characteristic of DSBAR 106 as an example of the individual frequency response characteristics of DSBAR 106 and DSBAR 708. DSBAR 106 exhibits a flat in-band response that is sufficiently broad to transmit the full bandwidth of an embodiment of modulated electrical signal S_{M} resulting from modulating an approximately 1.9 GHz carrier signal S_{C} with an embodiment of electrical information signal S₁ having a data rate greater than 100 Mbit/s. Each of the DSBARs subjects the electrical signal passing through it to the frequency response characteristic shown by the broken line in FIG. 17. The resulting frequency response of acoustic coupler 700 is shown by a solid line in FIG. 17. Acoustic coupler 700 has a flat in-band response and a steep transition between the pass band and the stop band. Moreover, the frequency response continues to fall as the frequency deviation from the center frequency increases, resulting in a large attenuation in the stop band.

The breakdown voltage of acoustic coupler 700 may be increased by structuring DSBARs 106 and 708 similarly to IDSBAR 206 described above with reference to FIG. 6, or similarly to IDSBAR 306 described above with reference to FIG. 8. Alternatively, the breakdown voltage of acoustic coupler 700 may be increased without additional layers simply by reconfiguring the way in which electrical circuit 740 connects the DSBARs in series, as will be described next.

(b) DSBARs Connected in Series by Connecting FBARs in Antiparallel

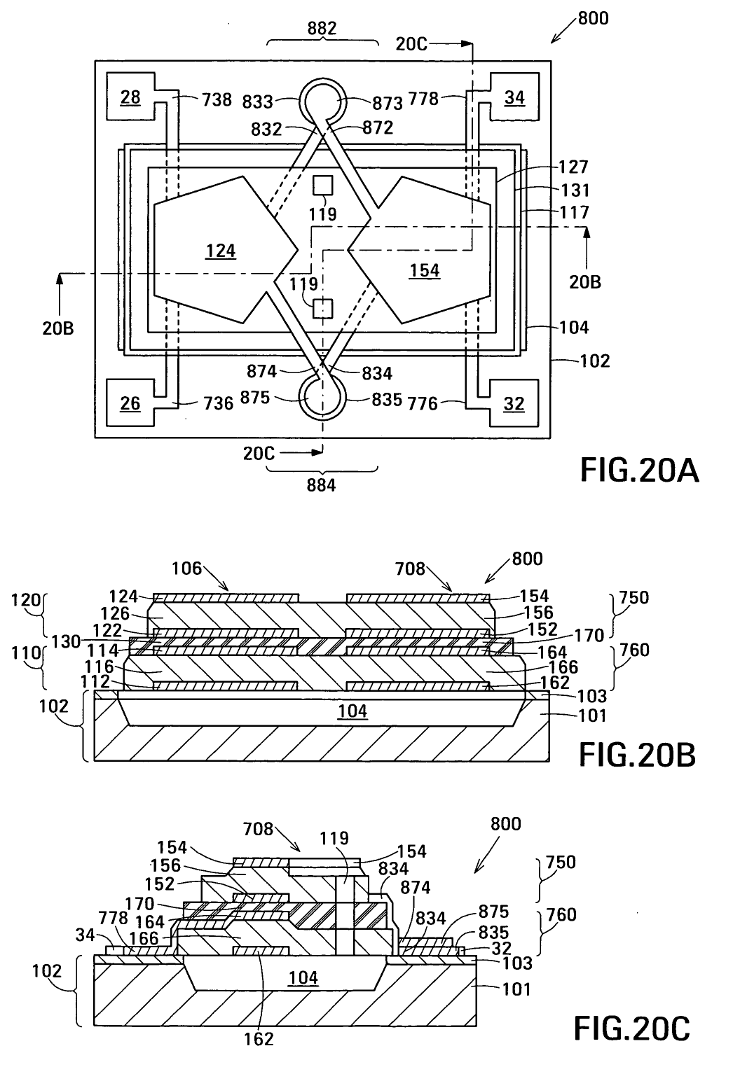

FIG. 19 is a schematic diagram showing an example of an acoustic coupler 800 in accordance with an eighth embodiment of the invention. FIG. 20A is a plan view showing a practical example of acoustic coupler 800. FIGS. 20B and 20C are cross-sectional views along section lines 20B-20B and 20-20C, respectively, shown in FIG. 20A. The same reference numerals are used to denote the elements of acoustic coupler 800 in FIG. 19 and in FIGS. 20A-20C. Acoustic coupler 800 comprises inputs 26, 28, outputs 32, 34, decoupled stacked bulk acoustic resonator (DSBAR) 106, DSBAR 708 and an electrical circuit 840 that connects DSBARs 106 and 708 in series between the inputs and the outputs. Acoustic coupler 800 provides a greater breakdown voltage than acoustic coupler 700 described above with reference to FIGS. 16 and 18A-18C without additional insulating layers.

When used as electrically-isolating acoustic coupler 16 in acoustic galvanic isolator 10 shown in FIG. 1, acoustic coupler 800 acoustically couples modulated electrical signal S_{M} from inputs 26, 28 to outputs 32, 34 while providing electrical isolation between inputs 26, 28 and outputs 32, 34. Thus, acoustic coupler 800 effectively galvanically isolates output terminals 36, 38 from input terminals 22, 24, and allows the output terminals to differ in voltage from the input terminals by a voltage up to its specified breakdown voltage.

DSBARs 106 and 708, including acoustic decouplers 130 and 170, and substrate 102 of acoustic coupler 800 are identical in structure and operation to DSBARs 106 and 708 and substrate 102 of acoustic coupler 700 described above with reference to FIGS. 16 and 18A-18C and therefore will not be described again here.

Electrical circuit 840 differs from electrical circuit 740 of acoustic coupler 700 described above with reference to FIG. 16 as follows. In acoustic coupler 700, electrical circuit 740 connects DSBARs 106 and 708 in series between inputs 26, 28 and outputs 32, 34 by connecting FBAR 120 of DSBAR 106 in parallel with FBAR 750 of DSBAR 708. In acoustic coupler 800, electrical circuit 840 connects DSBARs 106 and 708 in series between inputs 26, 28 and outputs 32, 34 by connecting FBAR 120 of DSBAR 106 in anti-parallel with FBAR 750 of DSBAR 708. Connecting DSBARs 106 and 708 in series by connecting FBARs 120 and 750 in anti-parallel instead of in parallel locates the piezoelectric elements 126 and 156 of FBARs 120 and 750, respectively, in the electrical paths between inputs 26, 28 and outputs 32, 34, where piezoelectric elements 126 and 156 provide additional electrical isolation. Consequently, for a given piezoelectric material and piezoelectric element thickness and for a given acoustic decoupler structure and materials, acoustic coupler 800 has a greater breakdown voltage than acoustic coupler 700, yet has the same number of constituent layers.

In electrical circuit 840, conductor 882 connects electrode 122 of FBAR 120 of DSBAR 106 to electrode 154 of FBAR 750 of DSBAR 708 and conductor 884 connects electrode 124 of FBAR 120 of DSBAR 106 to electrode 124 of FBAR 750 of DSBAR 708. Of the eight possible electrical paths between inputs 26, 28 and outputs 32, 34, the two electrical paths between input 28 and output 34, one via conductor 884 and one via conductor 882, are the shortest and therefore most susceptible to electrical breakdown. Electrical circuit 840 locates piezoelectric element 126 in series with acoustic decouplers 130 and 170 in the electrical path via conductor 884 between input 28 and output 34 and additionally locates piezoelectric element 156 in series with acoustic decouplers 130 and 170 in the electrical path via conductor 882 between input 28 and output 34. The piezoelectric material of piezoelectric elements 126 and 156 typically has a high resistivity and a high breakdown field, and piezoelectric elements 126 and 156 are each typically substantially thicker than acoustic decouplers 130 and 170 that are the sole providers of electrical isolation in above-described acoustic coupler 700. Consequently, for similar dimensions, materials and layer thicknesses, acoustic coupler 800 therefore typically has a greater breakdown voltage than acoustic-coupler 700 described above with reference to FIG. 16. Typically, for similar dimensions, materials and layer thicknesses, acoustic coupler 800 has a breakdown voltage similar to that of an embodiment of acoustic decoupler 700 incorporating the IDSBARs described above with reference to FIG. 6, but is simpler to fabricate because it has fewer layers.

In acoustic coupler 800, at least piezoelectric elements 126 and 156 electrically isolate inputs 26, 28 from outputs 32, 34. Since piezoelectric elements 126 and 156 provide electrical isolation, acoustic couplers 130 and 170 need not be electrically insulating. However, embodiments of acoustic coupler 800 in which acoustic couplers 130 and 170 are electrically insulating typically have a greater breakdown voltage than embodiments in which electrical isolation is provided only by piezoelectric elements 126 and 156.

In the practical example of acoustic coupler 800 shown in FIGS. 20A-20C, inputs 26, 28 shown in FIG. 19 are embodied as terminal pads 26, 28 respectively, and outputs 32, 34 shown in FIG. 19 are embodied as terminal pads 32, 34, respectively. Terminal pads 26, 28, 32 and 34 are located on the major surface of substrate 102. Electrical circuit 840 shown in FIG. 19 is composed of electrical traces 736, 738, 776 and 778 described above with reference to FIGS. 18A-18C. Additionally, electrical circuit 840 comprises connection pads 833 and 835 located on the major surface of substrate 102 and connection pads 873 and 875 located in electrical contact with connection pads 833 and 835, respectively. An electrical trace 832 extends from electrode 122 of FBAR 120 to connection pad 833 and an electrical trace 872 extends from electrode 154 of FBAR 750 to connection pad 873 in electrical contact with connection pad 833. Connection pads 833, 873 and electrical traces 832 and 872 collectively constitute conductor 882 that connects electrode 122 of FBAR 120 to electrode 154 of FBAR 750. An electrical trace 834 extends from electrode 152 of FBAR 750 to connection pad 835 and an electrical trace 874 extends from electrode 124 of FBAR 120 to connection pad 875 in electrical contact with connection pad 835. Connection pads 835, 875 and electrical traces 834 and 874 collectively constitute conductor 884 that connects electrode 152 of FBAR 750 to electrode 124 of FBAR 120.

Electrical traces 832 and 834 extend over parts of acoustic decoupling layer 131, parts of piezoelectric layer 117 and parts of the major surface of substrate 102 and electrical traces 872 and 874 extend over parts of piezoelectric layer 126, parts of acoustic decoupling layer 131, parts of piezoelectric layer 117 and parts of the major surface of substrate 102.

The breakdown voltage of acoustic coupler 800 may be further increased by structuring DSBARs 106 and 708 similarly to IDSBAR 206 described above with reference to FIG. 6, or similarly to IDSBAR 306 described above with reference to FIG. 8.

6. Fabrication of Acoustic Galvanic Isolators

Thousands of acoustic galvanic isolators similar to acoustic galvanic isolator 10 are fabricated at a time by wafer-scale fabrication. Such wafer-scale fabrication makes the acoustic galvanic isolators inexpensive to fabricate. The wafer is selectively etched to define a cavity in the location of the electrically-isolating acoustic coupler 16 of each acoustic galvanic isolator to be fabricated on the wafer. The cavities are filled with sacrificial material and the surface of the wafer is planarized. The local oscillator 12, modulator 14 and demodulator 18 of each acoustic galvanic isolator to be fabricated on the wafer are fabricated in and on the surface of the wafer using conventional semiconductor fabrication processing. The fabricated circuit elements are then covered with a protective layer. Exemplary materials for the protective layer are aluminum nitride and silicon nitride.

Embodiments of acoustic couplers 100, 400, 500, 600, 700 and 800 described above with reference to FIGS. 4A-4C, 11A-11C, 13A-13C, 15, 18A-18C and 20A-20C, respectively, are then fabricated by sequentially depositing and patterning the following layers: a first layer of electrode material, a first layer of piezoelectric material, a second layer of electrode material, a layer of acoustic decoupling material or the layers of an acoustic Bragg structure, a third layer of electrode material, a second layer of piezoelectric material and a fourth layer of electrode material. These layers form the one or more DSBARs and the electrical circuits of each acoustic coupler. The electrical circuits additionally connect each acoustic coupler to exposed connection points on modulator 14 and demodulator 18.

Embodiments of acoustic coupler 200 described above with reference to FIGS. 7A-7C and embodiments of acoustic couplers 400, 500, 600, 700 and 800 comprising an IDSBAR described above with reference to FIGS. 7A-7C are fabricated as just described, except that a quarter-wave layer 217 of electrically-insulating material and one or more layers constituting acoustic decoupler 230 are deposited and patterned after the after the one or more layers constituting acoustic decoupler 130 have been deposited and patterned. Embodiments of acoustic coupler 300 described above with reference to FIGS. 9A-9C and embodiments of acoustic couplers 400, 500, 600, 700 and 800 comprising an IDSBAR described above with reference to FIGS. 9A-9C are fabricated as just described, except that a first half-wave layer 317 of electrically-insulating material is deposited and patterned before, and a second half-wave layer 327 of electrically-insulating material is deposited and patterned after, the one or more layers constituting acoustic decoupler 130 have been deposited and patterned.

After the acoustic couplers have been fabricated, the sacrificial material is removed to leave the DSBAR(s) of each acoustic coupler suspended over its/their respective cavity. Access holes shown at 119 provide access to the sacrificial material to facilitate removal. The protective material is then removed from the fabricated circuit elements. The substrate is then divided into individual acoustic galvanic isolators each similar to acoustic galvanic isolator 10. An exemplary process that can be used to fabricate DSBARs is described in more detail in United States patent application publication no. 2005 0 093 654, assigned to the assignee of this disclosure and incorporated by reference, and can be adapted to fabricate the DSBARs of the acoustic galvanic isolators described above.

Some alternatives will now be described with reference to acoustic decoupler 100 described above with reference to FIGS. 2 and 4A-4C. Similar alternatives exist with respect to above-described acoustic couplers 200, 300, 400, 500, 600, 700 and 800, but these alternatives will not be individually described. In a first alternative, acoustic couplers 100 are fabricated on a different wafer from that on which local oscillators 12, modulators 14 and demodulators 18 are fabricated. This avoids the need for local oscillators 12, modulators 14 and demodulators 18 to be process-compatible with acoustic couplers 100. In this case, the acoustic galvanic isolators may be made by using a wafer bonding process to join the respective wafers to form a structure similar to that described by John D. Larson III et al. with reference to FIGS. 8A-8E of United States patent application publication no. 2005 0 093 659, assigned to the assignee of this disclosure and incorporated by reference.

In a further alternative, local oscillators 12, modulators 14 and acoustic couplers 100 are fabricated on one wafer and corresponding demodulators 18 are fabricated on the other wafer. The wafers are then bonded together as just described to form the acoustic galvanic isolators. Alternatively, the local oscillators 12 and modulators 14 are fabricated on one wafer and the acoustic couplers 100 and demodulators 18 are fabricated on the other wafer. The wafers are then bonded together as just described to form the acoustic galvanic isolators.

In another alternative suitable for use in applications in which acoustic galvanic isolators 10 are specified to have a large breakdown voltage between input terminals 22, 24 and output terminals 36, 38, multiple input circuits each comprising an instance of local oscillator 12 and an instance of modulator 14 and multiple output circuits each comprising an instance of demodulator 18 are fabricated in and on a semiconductor wafer. The wafer is then singulated into individual semiconductor chips each embodying a single input circuit or a single output circuit. The electrically-isolating acoustic coupler 16 of each acoustic galvanic isolator is fabricated as an acoustic coupler suspended over a cavity defined in a ceramic wafer having conductive traces located on its major surface. For each acoustic galvanic isolator fabricated on the wafer, one semiconductor chip embodying an input circuit and one semiconductor chip embodying an output circuit are mounted on the ceramic wafer in electrical contact with the conductive traces. For example, the semiconductor chips may be mounted on the ceramic wafer by ball bonding or flip-chip bonding. Ceramic wafers with attached semiconductor chips can also be used in the above-described two wafer structure.

In an exemplary embodiment of acoustic galvanic isolator 10 operating at a carrier frequency of about 1.9 GHz, the material of electrodes 112, 114, 122 and 124 (and electrodes 152, 154, 162 and 164 when present), is molybdenum. Each of the electrodes has a thickness of about 300 nm and is pentagonal in shape with an area of about 12,000 square μm. A different area gives a different characteristic impedance. The non-parallel sides of the electrodes minimize lateral modes in the respective FBARs as described by Larson III et al. in U.S. Pat. No. 6,215,375, assigned to the assignee of this disclosure and incorporated by reference. The metal layers in which electrodes 112, 114, 122 and 124 (and electrodes 152, 154, 162 and 164 when present) are defined are patterned such that, in respective planes parallel to the major surface of the wafer, electrodes 112 and 114 of FBAR 110 have the same shape, size, orientation and position and electrodes 122 and 124 of FBAR 120 have the same shape, size, orientation and position. Moreover, when present, electrodes 152 and 154 of FBAR 150 and FBAR 750 have the same shape, size, orientation and position, and electrodes 162 and 164 of FBAR 160 and FBAR 760 have the same shape, size, orientation and position. Typically, electrodes 114 and 122 additionally have the same shape, size, orientation and position and, when present, electrodes 154 and 162 or electrodes 152 and 164 additionally have the same shape, size, orientation and position. Alternative electrode materials include such metals as tungsten, niobium and titanium. The electrodes may have a multi-layer structure.

The material of piezoelectric elements 116 and 126 (and, when present, piezoelectric elements 156 and 166) is aluminum nitride. Each piezoelectric element has a thickness of about 1.4 μm. Alternative piezoelectric materials include zinc oxide, cadmium sulfide and poled ferroelectric materials such as perovskite ferroelectric materials, including lead zirconium titanate (PZT), lead metaniobate and barium titanate.

Possible structures and materials for acoustic decouplers 130 and 170 are described above with reference to FIGS. 5A and 5B.

In embodiments of acoustic coupler 200 described above with reference to FIGS. 7A-7C, and in embodiments of acoustic couplers 400, 500, 600, 700 and 800 comprising an IDSBAR described above with reference to FIGS. 7A-7C, the material of quarter-wave acoustically-resonant electrical insulator 216 is aluminum nitride. Each acoustically-resonant electrical insulator has a thickness of about 1.4 μm. Alternative materials include aluminum oxide (Al₂O₃) and non-piezoelectric aluminum nitride. Possible structures and materials for second acoustic decoupler 230 are described above with reference to FIGS. 5A and 5B.

In embodiments of acoustic coupler 300 described above with reference to FIGS. 9A-9C and in embodiments of acoustic couplers 400, 500, 600, 700 and 800 comprising an IDSBAR described above with reference to FIGS. 9A-9C, the material of half-wave acoustically-resonant electrical insulators 316 and 326 is aluminum nitride. Each half-wave acoustically-resonant electrical insulator has a thickness of about 2.8 μm. Alternative materials include aluminum oxide (Al₂O₃) and non-piezoelectric (ceramic) aluminum nitride.

In acoustic couplers in accordance with the invention, the directions of the acoustic signals may be the opposite of the directions exemplified above. For example, in acoustic coupler 100 described above with reference to FIGS. 2 and 4A-4C, inputs 26, 28 may be connected to upper FBAR 120 and outputs 32, 34 may be connected to the lower FBAR 110.

7. Galvanic Isolation Method

FIG. 21 is a flow chart showing an example of a method 190 in accordance with an embodiment of the invention for galvanically isolating an information signal. In block 192, an electrically-isolating acoustic coupler is provided. In block 193, a carrier signal is provided. In block 194, the carrier signal is modulated with the information signal to form a modulated electrical signal. In block 195, the modulated electrical signal is acoustically coupled through the electrically-isolating acoustic coupler. In block 196, the information signal is recovered from the modulated electrical signal acoustically coupled though the acoustic coupler. In an embodiment, the electrically-isolating acoustic coupler comprises film bulk acoustic resonators (FBARs).

This disclosure describes the invention in detail using illustrative embodiments. However, the invention defined by the appended claims is not limited to the precise embodiments described.

We claim:

1. An acoustic galvanic isolator, comprising:
a carrier signal source;
a modulator connected to receive an information signal and the carrier signal;
a demodulator; and
an electrically-isolating acoustic coupler connected between the modulator and the demodulator.

2. The acoustic galvanic isolator of claim 1, in which:
the electrically-isolating acoustic coupler comprises a decoupled stacked bulk acoustic resonator (DSBAR); and
the DSBAR comprises a first film bulk acoustic resonator (FBAR), a second FBAR, and an acoustic decoupler between the FBARs.

3. The acoustic galvanic isolator of claim 2, additionally comprising:
a first electrical circuit electrically connecting the modulator to the first FBAR; and
a second electrical circuit electrically connecting the demodulator to the second FBAR.

4. The acoustic galvanic isolator of claim 2, in which the electrically-isolating acoustic coupler comprises no more than one decoupled stacked bulk acoustic resonator (DSBAR).

5. The acoustic galvanic isolator of claim 4, in which the acoustic decoupler is electrically insulating and is the sole provider of electrical isolation between the modulator and the demodulator.

6. The acoustic galvanic isolator of claim 2, additionally comprising an acoustically-resonant electrical insulator located between the FBARs.

7. The acoustic galvanic isolator of claim 6, in which the acoustically-resonant electrical insulator comprises a layer of electrically-insulating material differing in acoustic impedance from the FBARs by less than one order of magnitude.

8. The acoustic galvanic isolator of claim 6, in which the acoustically-resonant electrical insulator comprises a layer of electrically-insulating material matched in acoustic impedance with the FBARs.

9. The acoustic galvanic isolator of claim 6, in which:
the acoustic galvanic isolator additionally comprises an additional acoustic decoupler located between the FBARs; and
the acoustically-resonant electrical insulator comprises a quarter-wave layer of electrically-insulating material and is located between the acoustic decouplers.

10. The acoustic galvanic isolator of claim 9, in which the layer of electrically-insulating material is a one quarter-wave layer.

11. The acoustic galvanic isolator of claim 9, in which at least one of the acoustic decouplers is electrically insulating.

12. The acoustic galvanic isolator of claim 6, in which:
the acoustically-resonant electrical insulator is a first acoustically-resonant electrical insulator and comprises a half-wave layer of electrically-insulating material;
the acoustic galvanic isolator additionally comprises a second acoustically-resonant electrical insulator between the FBARs, the second acoustically-resonant electrical insulator comprising a half-wave layer of electrically-insulating material; and
the acoustic decoupler is located between the first half-wave acoustically-resonant electrical insulator and the second half-wave acoustically-resonant electrical insulator.

13. The acoustic galvanic isolator of claim 12, in which the acoustic decoupler is electrically insulating.

14. The acoustic galvanic isolator of claim 1, in which the electrically-isolating acoustic coupler comprises a film acoustically-coupled transformer (FACT).

15. The acoustic galvanic isolator of claim 14, in which the FACT comprises:
a first decoupled stacked bulk acoustic resonator (DSBAR) and a second DSBAR, each of the DSBARs comprising a first film bulk acoustic resonator (FBAR), a second FBAR and an acoustic decoupler between the first FBAR and the second FBAR; and
a first electrical circuit interconnecting the first FBARs of the DSBARs and connecting the first FBARs to the modulator; and
a second electrical circuit interconnecting the second FBARs of the DSBARs and connecting the second FBARs to the demodulator.

16. The acoustic galvanic isolator of claim 15 in which:
the first electrical circuit connects the first FBARs in anti-parallel; and
the second electrical circuit connects the second FBARs in series.

17. The acoustic galvanic isolator of claim 16, in which:
each of the FBARs comprises a piezoelectric element; and
the piezoelectric element of the second FBAR of each DSBAR collectively provide electrical isolation between the modulator and the demodulator.

18. The acoustic galvanic isolator of claim 15, in which:
the first electrical circuit connects the first FBARs in series; and
the second electrical circuit connects the second FBARs in series.

19. The acoustic galvanic isolator of claim 18, in which:
each of the FBARs comprises a piezoelectric element; and
the piezoelectric elements of both FBARs of each DSBAR collectively provide electrical isolation between the modulator and the demodulator.

20. The acoustic galvanic isolator of claim 18, in which:
the modulator has a differential output connected to the first electrical circuit; and
the demodulator has a differential input connected to the second electrical circuit.

21. The acoustic galvanic isolator of claim 18, in which:
the FACT is a first FACT; and
the acoustic galvanic isolator additionally comprises a second FACT interposed between the modulator and the acoustic coupler, the second FACT comprising a first DSBAR and a second DSBAR, each DSBAR comprising a first FBAR and a second FBAR, the first FBARs connected in antiparallel and to the output of the modulator, the second FBARs connected in series and to the first electrical circuit.

22. The acoustic galvanic isolator of claim 21, in which an acoustic signal travels in the second FACT in an opposite direction to an acoustic signal in the first FACT.

23. The acoustic galvanic isolator of claim 15, in which:
each of the FBARs comprises a piezoelectric element; and
the piezoelectric element of the second FBAR of each DSBAR provides electrical isolation between the modulator and the demodulator.

24. The acoustic galvanic isolator of claim 1, in which the electrically-isolating acoustic coupler comprises series-connected decoupled stacked bulk acoustic resonators (DSBARs).

25. The acoustic galvanic isolator of claim 23, in which the acoustic coupler comprises:
a first decoupled stacked bulk acoustic resonator (DSBAR) and a second DSBAR, each of the DSBARs comprising a first film bulk acoustic resonator (FBAR), a second FBAR, and an acoustic decoupler between the first FBAR and the second FBAR; and
an electrical circuit connecting the DSBARs in series between the modulator and the demodulator.

26. The acoustic galvanic isolator of claim 25, in which the electrical circuit connects the DSBARs in series by connecting the second FBARs of the DSBARs in parallel.

27. The acoustic galvanic isolator of claim 26, in which the acoustic decoupler of at least one of the DSBARs is electrically insulating and provides electrical isolation between the modulator and the demodulator.

28. The acoustic galvanic isolator of claim 25, in which the electrical circuit connects the DSBARs in series by connecting the second FBARs of the DSBARs in anti-parallel.

29. The acoustic galvanic isolator of claim 28, in which:
each of the FBARs comprises a piezoelectric element; and
the piezoelectric element of the second FBAR of each DSBAR provides electrical isolation between the modulator and the demodulator.

30. The acoustic galvanic isolator of claim 28, in which the acoustic decoupler of at least one of the DSBARs is electrically insulating and provides additional electrical isolation between the modulator and the demodulator.

31. The acoustic galvanic isolator of claim 1, in which the electrically-isolating acoustic coupler comprises film bulk acoustic resonators (FBARs).

32. A method for galvanically isolating an information signal, the method comprising:
providing an electrically-isolating acoustic coupler;
providing a carrier signal;
modulating the carrier signal with the information signal to form a modulated electrical signal;
acoustically coupling the modulated electrical signal through the electrically-isolating acoustic coupler; and
recovering the information signal from the modulated electrical signal acoustically coupled through the electrically-isolating acoustic coupler.

33. The method of claim 32, in which the acoustically coupling comprises:
generating an acoustic signal in response to the modulated electrical signal; and
passing the acoustic signal through an electrically-insulating acoustic decoupler.

34. The method of claim 33, in which the acoustically coupling additionally comprises passing the acoustic signal through an acoustically-resonant electrical insulator.

35. The method of claim 34, in which the acoustically-resonant electrical insulator is a quarter-wave acoustically-resonant electrical insulator.

36. The method of claim 34, in which the acoustically-resonant electrical insulator is a half-wave acoustically-resonant electrical insulator.

37. The method of claim 32, in which the acoustically coupling comprises:
generating antiphase acoustic signals in response to the modulated electrical signal;
passing the antiphase acoustic signals through respective acoustic decouplers;
converting the acoustic signals passed through the acoustic decouplers to respective recovered electrical signals; and
summing the recovered electrical signals.

38. The method of claim 32, in which the acoustically coupling comprises repetitively performing a process comprising:
generating an acoustic signal in response to a first electrical signal, the first electrical signal being the modulated electrical signal in the first performance of the process and being a second electrical signal in each subsequent performance;
passing the acoustic signal through an acoustic decoupler; and
converting the acoustic signal passed through the acoustic decoupler to provide the second electrical signal in all but the last performance and to provide the modulated electrical signal acoustically coupled through the electrically-isolating acoustic coupler in the last performance.
